(19) United States
(12) Patent Application Publication
(10) Pub. No.: US 2026/0206314 A1
(43) Pub. Date: Jul. 16, 2026

(54) SEMICONDUCTOR DEVICE AND METHOD FOR FABRICATING THEREOF

(71) Applicant: Samsung Electronics Co., Ltd., Suwon-si (KR)

(72) Inventors: Deok Hwan KIM, Suwon-si (KR); Han Byul CHOI, Suwon-si (KR)

(21) Appl. No.: 19/352,231

(22) Filed: Oct. 7, 2025

(30) Foreign Application Priority Data
Jan. 10, 2025 (KR) 10-2025-0003804

(51) Int. Cl. H10D 86/00; H10D 86/01

(52) U.S. Cl. CPC H10D 86/215; H10D 86/011

(57) ABSTRACT

A semiconductor device comprises a field insulating film which includes a first surface and a second surface opposite to each other in a first direction, a first protruding insulation pattern disposed on the first surface of the field insulating film, a second protruding insulation pattern disposed on the first surface of the field insulating film, and spaced apart from the first protruding insulation pattern in a second direction, a thickness of the second protruding insulation pattern in the first direction being different from a thickness of the first protruding insulation pattern in the first direction, a channel region disposed between the first protruding insulation pattern and the second protruding insulation pattern and a gate electrode disposed on the channel region, the first protruding insulation pattern, and the second protruding insulation pattern.

### CROSS-REFERENCE TO RELATED APPLICATION

This application claims priority to Korean Patent Application No. 10-2025-0003804 filed on Jan. 10, 2025 in the Korean Intellectual Property Office, and all the benefits accruing therefrom under 35 U.S.C. 119, the contents of which in their entirety are herein incorporated by reference.

### BACKGROUND

### 1. Technical Field

The present disclosure relates to a semiconductor device and method for fabricating the same.

### 2. Description of the Related Art

As one of scaling technologies for increasing density of a semiconductor device, a multi gate transistor in which a multi-channel active pattern (or a silicon body) having a fin or nanowire shape is formed on a substrate and a gate is formed on a surface of the multi-channel active pattern has been proposed.

Since such a multi gate transistor utilizes a three-dimensional channel, scaling is easily performed. Further, even if a gate length of the multi gate transistor is not increased, the current control capability may be improved. Furthermore, a SCE (short channel effect) in which potential of a channel region is influenced by a drain voltage may be effectively suppressed.

On the other hand, as a pitch size of the semiconductor device decreases, research for reducing the capacitance between contacts in the semiconductor device and ensuring electrical stability is required.

### SUMMARY

Aspects of the present disclosure provide a semiconductor device capable of improving element/device performance and degree of integration of the elements/devices.

Aspects of the present disclosure also provide a method for fabricating a semiconductor device capable of improving element/device performance and degree of integration of the elements/devices.

However, aspects of the present disclosure are not restricted to the ones set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor device comprising a field insulating film which includes a first surface and a second surface opposite to each other in a first direction, a first protruding insulation pattern disposed on the first surface of the field insulating film, a second protruding insulation pattern disposed on the first surface of the field insulating film, and spaced apart from the first protruding insulation pattern in a second direction, a thickness of the second protruding insulation pattern in the first direction being different from a thickness of the first protruding insulation pattern in the first direction, a channel region disposed between the first protruding insulation pattern and the second protruding insulation pattern and a gate electrode disposed on the channel region, the first protruding insulation pattern, and the second protruding insulation pattern, wherein the gate electrode includes a first connecting gate electrode, a second connecting gate electrode, and a body gate electrode disposed between the first connecting gate electrode and the second connecting gate electrode, wherein the first connecting gate electrode overlaps the first protruding insulation pattern in the first direction, wherein the second connecting gate electrode overlaps the second protruding insulation pattern in the first direction, and wherein the body gate electrode is disposed between the first protruding insulation pattern and the second protruding insulation pattern.

According to another aspect of the present disclosure, there is provided a semiconductor device comprising a field insulating film which includes an upper surface and a lower surface opposite to each other in a vertical direction, a channel region disposed above the upper surface of the field insulating film, the channel region including a first side wall and a second side wall opposite to each other in a horizontal direction, a first protruding insulation pattern disposed on the first side wall of the channel region, and in contact with the upper surface of the field insulating film and a gate structure disposed on the channel region and the first protruding insulation pattern, the gate structure including a gate electrode and a gate insulating film, wherein the gate electrode includes a body gate electrode disposed on the first side wall of the channel region and the second side wall of the channel region, and a first connecting gate electrode and a second connecting gate electrode extending from the body gate electrode in the horizontal direction, wherein a thickness of the body gate electrode in the horizontal direction on the first side wall of the channel region is equal to a thickness of the body gate electrode in the horizontal direction on the second side wall of the channel region, wherein a height of the body gate electrode in the vertical direction is greater than a height of the first connecting gate electrode in the vertical direction and a height of the second connecting gate electrode in the vertical direction, wherein the first connecting gate electrode is disposed on the first side wall of the channel region, and overlaps the first protruding insulation pattern in the vertical direction, wherein the second connecting gate electrode is disposed on the second side wall of the channel region, wherein each of the first connecting gate electrode and the second connecting gate electrode includes an upper surface and a lower surface opposite to each other in the vertical direction, wherein the lower surface of the first connecting gate electrode and the lower surface of the second connecting gate electrode face the field insulating film, and wherein a height from the lower surface of the field insulating film to the upper surface of the first connecting gate electrode is greater than a height from the lower surface of the field insulating film to the upper surface of the second connecting gate electrode.

According to another aspect of the present disclosure, there is provided a semiconductor device comprising a field insulating film which includes a first surface and a second surface opposite to each other in a first direction a first protruding insulation pattern disposed on the first surface of the field insulating film, a second protruding insulation pattern disposed on the first surface of the field insulating film, and spaced apart from the first protruding insulation pattern in a second direction, a height of the second protruding insulation pattern in the first direction being different from a height of the first protruding insulation pattern in the first direction, a channel region spaced apart from the first surface of the field insulating film in the first direction, a gate electrode disposed on the first protruding insulation pattern and the second protruding insulation pattern, and enclosing the channel region, source/drain patterns connected to the channel region, and disposed on both sides of the gate electrode and a gate contact disposed on the gate electrode, and electrically connected to the gate electrode, wherein the gate electrode includes a first connecting gate electrode, a second connecting gate electrode, and a body gate electrode disposed between the first connecting gate electrode and the second connecting gate electrode, wherein the first connecting gate electrode overlaps the first protruding insulation pattern in the first direction, wherein the second connecting gate electrode overlaps the second protruding insulation pattern in the first direction, wherein the body gate electrode is disposed between the first protruding insulation pattern and the second protruding insulation pattern, and wherein a height of the body gate electrode in the first direction is greater than a height of the first connecting gate electrode in the first direction.

Specific details of other embodiments are included in the detailed description and drawings.

### BRIEF DESCRIPTION OF DRAWINGS

The above and other aspects and features of the present disclosure will become more apparent by describing in detail embodiments thereof with reference to the attached drawings, in which:

FIG. 1 is a layout diagram for describing a semiconductor device according to some embodiments.

FIG. 2 is a cross-sectional view taken along A-A of FIG. 1.

FIG. 3 is a cross-sectional view taken along B-B of FIG. 1.

FIG. 4 is a cross-sectional view taken along C-C of FIG. 1.

FIG. 5 is a cross-sectional view taken along D-D of FIG. 1.

FIGS. 6 and 7 are diagrams for explaining a semiconductor device according to some embodiments.

FIGS. 8 and 9 are diagrams for explaining a semiconductor device according to some embodiments.

FIG. 10 is a diagram for explaining a semiconductor device according to some embodiments.

FIGS. 11 to 14 are diagrams for explaining a semiconductor device according to some embodiments.

FIGS. 15 and 16 are diagrams for explaining a semiconductor device according to some embodiments.

FIGS. 17 and 18 are diagrams for explaining a semiconductor device according to some embodiments.

FIG. 19 is a diagram for explaining a semiconductor device according to some embodiments.

FIGS. 20 to 22 are diagrams for explaining a semiconductor device according to some embodiments.

FIGS. 23 and 24 are diagrams for explaining a semiconductor device according to some embodiments.

FIGS. 25 to 46 are intermediate stage diagrams for explaining a method for fabricating a semiconductor device according to some embodiments.

### DETAILED DESCRIPTION OF THE EMBODIMENTS

Although the first, second, and the like are used herein to describe various elements or components, it is obvious that these elements or components are not limited by these terms. These terms are merely used to distinguish one element or component from another element or component. Accordingly, it should be understood that the first element or component as mentioned below may be the second element or component within the technical idea of the present disclosure. For example, a term that is referenced with a particular ordinal number (e.g., “first” in a particular claim) may be described elsewhere with a different ordinal number (e.g., “second” in the specification or another claim).

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

Spatially relative terms, such as “beneath,” “below,” “lower,” “above,” “upper,” “top,” “bottom,” “front,” “rear,” “vertical,” “horizontal,” “high,” “low,” and the like, may be used herein for ease of description to describe positional relationships, such as illustrated in the figures, for example. It will be understood that the spatially relative terms encompass different orientations of the device in addition to the orientation depicted in the figures.

Throughout the specification, “adjacent” may indicate a closest one or closest. For example, when a first element and a second element are adjacent to each other, the second element may be the closest one to the first element among second elements, and the first element may be the closest one to the second element among first elements. Similarly, when two elements are adjacent each other in a certain direction, the two elements may be the closest ones to each other in the certain direction. When multiple first elements are at the same distance from a second element, an adjacent first element to the second element may be any one of the closest first elements to the second element.

As used herein, components described as being “electrically connected” are configured such that an electrical signal can be transferred from one component to the other (although such electrical signal may be attenuated in strength as it is transferred and may be selectively transferred).

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, the term “dummy” is used to refer to a component that has the same or similar structure and shape as other components but does not have a substantial function and exists only as a pattern in the device. In certain embodiments, “dummy” may be used to a component that is placed in an intermediate step of a manufacturing process. For example, a dummy element may be removed and a non-dummy element may be formed in a later step at the place in which the dummy element was placed.

Although drawings of semiconductor devices according to some embodiments show a fin-shaped transistor (FinFET) including a channel region of a fin-shaped pattern shape, a transistor including a nanowire or a nanosheet, and a MBCFET™ (Multi-Bridge Channel Field Effect Transistor) as examples, embodiments are not limited thereto. The semiconductor device according to some embodiments may, of course, include a tunneling transistor (tunneling FET) or a three-dimensional (3D) transistor. Semiconductor devices according to some embodiments may, of course, include a planar transistor. In addition, the technical idea of the present disclosure may be applied to a transistor based on two-dimensional material (2D material based FETs) and/or a heterostructure of two-dimensional materials.

Further, semiconductor devices according to some embodiments may also include a bipolar junction transistor, a laterally diffused metal oxide semiconductor (LDMOS), or the like.

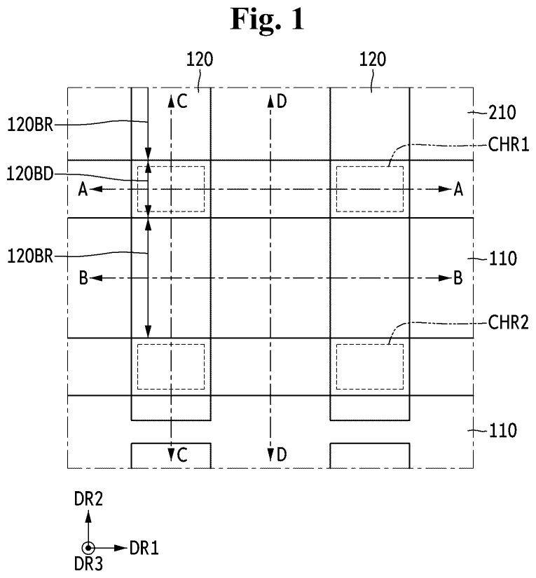

The semiconductor device according to some embodiments will be described referring to FIGS. 1 to 5.

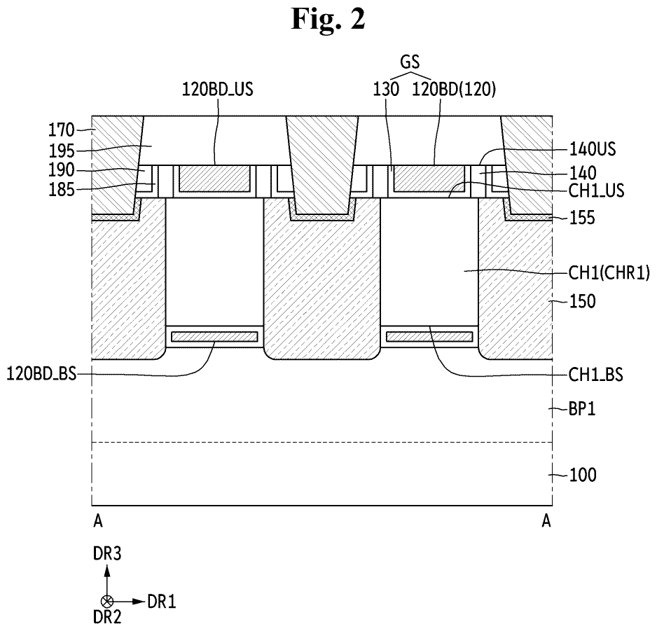

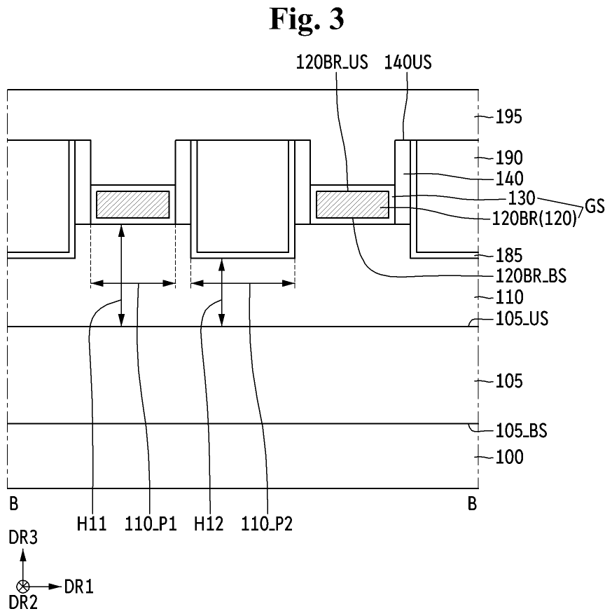

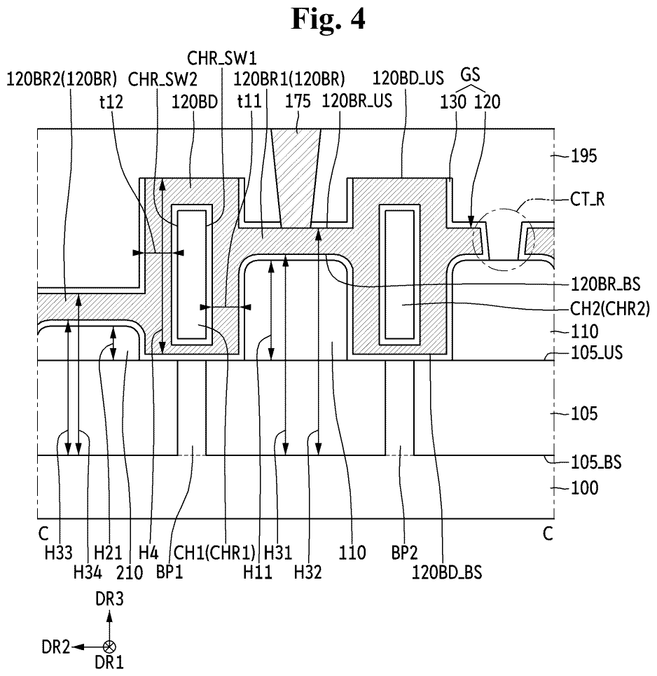

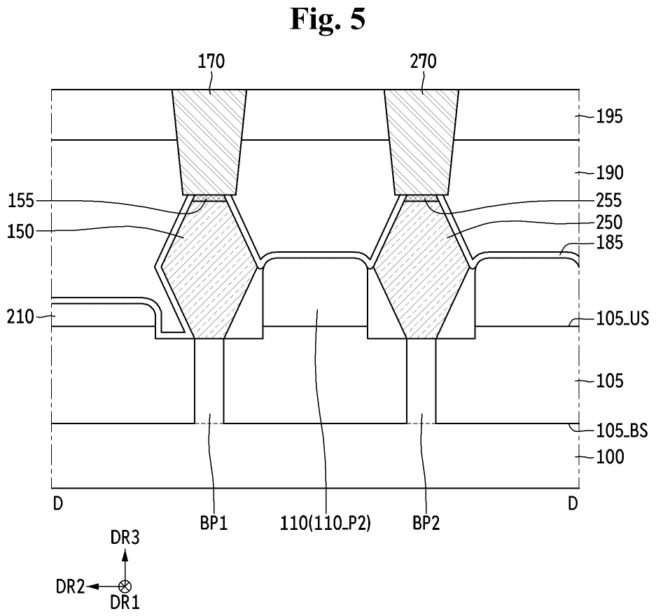

FIG. 1 is a layout diagram for describing a semiconductor device according to some embodiments. FIG. 2 is a cross-sectional view taken along A-A of FIG. 1. FIG. 3 is a cross-sectional view taken along B-B of FIG. 1. FIG. 4 is a cross-sectional view taken along C-C of FIG. 1. FIG. 5 is a cross-sectional view taken along D-D of FIG. 1.

For reference, FIG. 1 illustrates the semiconductor device except a front source/drain contact 170 and a front gate contact 175.

Referring to FIGS. 1 to 5, the semiconductor device according to some embodiments includes a field insulating film 105, a first channel region CHR1, a second channel region CHR2, a first protruding insulation pattern 110, a second protruding insulation pattern 210, a gate electrode 120, a first source/drain pattern 150 and a second source/drain pattern 250.

The first substrate 100 may be made of or may include a semiconductor material. The first substrate 100 may be a silicon substrate or an SOI (silicon on insulator) substrate. In certain embodiments, the first substrate 100 may include, for example, but is not limited to, silicon germanium, SGOI (silicon germanium on insulator), indium antimonide, lead telluride, indium arsenide, indium phosphide, gallium arsenide or gallium antimonide.

Each of a first lower pattern BP1 and a second lower pattern BP2 may protrude from the first substrate 100 in a third direction DR3. Each of the first lower pattern BP1 and the second lower pattern BP2 may extend lengthwise in a first direction DR1. The first lower pattern BP1 and the second lower pattern BP2 may be spaced apart from each other in a second direction DR2. The first and second directions DR1 and DR2 may be horizontal directions perpendicular to each other, and the third direction DR3 may be a vertical direction.

For example, the third direction DR3 may be a thickness direction of the first substrate 100. Each of the first direction DR1 and the second direction DR2 may be perpendicular to the third direction DR3. The first direction DR1 may be perpendicular to the second direction DR2.

Each of the first lower pattern BP1 and the second lower pattern BP2 may be formed by etching a part of the first substrate 100, and/or may include an epitaxial layer grown from the first substrate 100. Each of the first lower pattern BP1 and the second lower pattern BP2 may include silicon or germanium, which are elemental semiconductor materials. In certain embodiments, each of the first lower pattern BP1 and the second lower pattern BP2 may include a compound semiconductor, and may include, for example, a group IV-IV compound semiconductor or a group III-V compound semiconductor

The group IV-IV compound semiconductor may be, for example, a binary compound, a ternary compound including at least two of carbon (C), silicon (Si), germanium (Ge) or tin (Sn), or a compound obtained by doping these elements with a group IV element.

The group III-V compound semiconductor may be, for example, one of a binary compound, a ternary compound or a quaternary compound formed by combining at least one of aluminum (Al), gallium (Ga) or indium (In), which is a group III element, with one of phosphorus (P), arsenic (As) or antimonium (Sb), which is a group V element.

For example, the first lower pattern BP1 and the second lower pattern BP2 may include the same material.

The field insulating film 105 may be disposed on the first substrate 100. The field insulating film 105 may fill at least a part of a fin trench that separates the first lower pattern BP1 and the second lower pattern BP2.

The field insulating film 105 may be disposed on side walls of the first lower pattern BP1 and side walls of the second lower pattern BP2. The field insulating film 105 is not disposed on the upper side of the first lower pattern BP1 and the upper side of the second lower pattern BP2. For example, the field insulating film 105 does not cover an upper surface of the first lower pattern BP1 and an upper surface of the second lower pattern BP2.

The field insulating film 105 may include a first side 105_US and a second side 105_BS that are opposite to each other in the third direction DR3. The first side 105_US of the field insulating film may be an upper side (upper surface) of the field insulating film 105, and the second side 105_BS of the field insulating film may be a bottom side (bottom surface) of the field insulating film 105. The second side 105_BS of the field insulating film may face the first substrate 100. For example, the second side 105_BS of the field insulating film may be in contact with the first substrate 100.

As an example, the field insulating film 105 may entirely cover the side walls of the first lower pattern BP1 and the side walls of the second lower pattern BP2. Unlike the shown example, the field insulating film 105 may cover a part of the side walls of the first lower pattern BP1 and/or a part of the side walls of the second lower pattern BP2. In this case, taking the first lower pattern BP1 as an example, a part of the first lower pattern BP1 may protrude in the third direction DR3 beyond the first side 105_US of the field insulating film.

Although the first side 105_US of the field insulating film is shown to have a flat shape, this is only for convenience of explanation, and the embodiment is not limited thereto. The field insulating film 105 may include, for example, silicon oxide, silicon nitride, silicon oxynitride or a combination thereof. Although the field insulating film 105 is shown to be a single film, this is only for convenience of explanation, and the embodiment is not limited thereto. For example, the field insulating film 105 may be formed of multiple layers of films.

A first channel region CHR1 may be disposed on the first lower pattern BP1. The first channel region CHR1 may overlap the first lower pattern BP1 in the third direction DR3.

The first channel region CHR1 may be disposed above the first side 105_US of the field insulating film. In the semiconductor device according to some embodiments, the first channel region CHR1 may be spaced apart from the first lower pattern BP1 in the third direction DR3. The first channel region CHR1 may be spatially separated from the first lower pattern BP1 in the third direction DR3. The first channel region CHR1 may be spaced apart from the first side 105_US of the field insulating film in the third direction DR3.

The first channel region CHR1 may include a first channel pattern CH1 spaced apart from the first side 105_US of the field insulating film in the third direction DR3. The first channel pattern CH1 may include an upper side CH1_US and a bottom side CH1_BS that are opposite to each other in the third direction DR3. For example, the upper side CH1_US of the first channel pattern CH1 may be an upper surface or a top surface of the first channel pattern CH1, and the bottom side CH1_BS of the first channel pattern CH1 may be a bottom surface or a lower surface of the first channel pattern CH1. The bottom side CH1_BS of the first channel pattern may face the first lower pattern BP1 and the first substrate 100. The upper side CH1_US of the first channel pattern CH1 may be an upper side/surface of the first channel region CHR1. In the semiconductor device according to some embodiments, the bottom side CH1_BS of the first channel pattern CH1 may be a bottom side/surface of the first channel region CHR1.

The first channel region CHR1 may include a first side wall CHR_SW1 and a second side wall CHR_SW2 that are opposite to each other in the second direction DR2. The first side wall CHR_SW1 of the first channel region may be a first side wall of the first channel pattern CH1, and the second side wall CHR_SW2 of the first channel region may be a second side wall of the first channel pattern CH1.

The second channel region CHR2 may be disposed on the second lower pattern BP2. The second channel region CHR2 may overlap the second lower pattern BP2 in the third direction DR3. The second channel region CHR2 may include a second channel pattern CH2 spaced apart from the first side 105_US of the field insulating film in the third direction DR3.

The description of the second channel region CHR2 may be the same or substantially the same as the above-mentioned description of the first channel region CHR1.

As an example, one of the first channel region CHR1 and the second channel region CHR2 may be disposed in a PMOS formation region, and the other may be disposed in an NMOS formation region. As another example, the first channel region CHR1 and the second channel region CHR2 may be disposed in an NMOS formation region. As yet another example, the first channel region CHR1 and the second channel region CHR2 may be disposed in a PMOS formation region.

As an example, the first channel region CHR1 and the second channel region CHR2 may be disposed in a logic region. As another example, the first channel region CHR1 and the second channel region CHR2 may be disposed in an SRAM region. As yet another example, the first channel region CHR1 and the second channel region CHR2 may be disposed in an I/O region.

Each of the first channel region CHR1 and the second channel region CHR2 may include one of an elemental semiconductor material (e.g., silicon or germanium), a group IV-IV compound semiconductor or a group III-V compound semiconductor. The first channel region CHR1 may include the same material as the first lower pattern BP1, or may include a different material from the first lower pattern BP1. The second channel region CHR2 may include the same material as the second lower pattern BP2, or may include a different material from the second lower pattern BP2.

In the semiconductor device according to some embodiments, each of the first lower pattern BP1 and the second lower pattern BP2 may be a silicon lower pattern including silicon. Each of the first channel region CHR1 and the second channel region CHR2 may be a silicon channel pattern/region including silicon.

The first protruding insulation pattern 110 may be disposed on the field insulating film 105. The first protruding insulation pattern 110 may be disposed on the first side 105_US of the field insulating film. For example, the first protruding insulation pattern 110 may be in contact with the first side 105_US of the field insulating film.

The first protruding insulation pattern 110 may be disposed on the first side wall CHR_SW1 of the first channel region. The first protruding insulation pattern 110 may extend in the first direction DR1 along the first side wall CHR_SW1 of the first channel region.

The second protruding insulation pattern 210 may be disposed on the field insulating film 105. The second protruding insulation pattern 210 may be disposed on the first side 105_US of the field insulating film. For example, the second protruding insulation pattern 210 may be in contact with the first side 105_US of the field insulating film.

The second protruding insulation pattern 210 may be disposed on the second side wall CHR_SW2 of the first channel region. The second protruding insulation pattern 210 may extend in the first direction DR1 along the second side wall CHR_SW2 of the first channel region.

The first protruding insulation pattern 110 and the second protruding insulation pattern 210 may be spaced apart from each other in the second direction DR2. The first channel region CHR1 may be disposed between the first protruding insulation pattern 110 and the second protruding insulation pattern 210. For example, the second channel region CHR2 may be disposed between the first protruding insulation patterns 110 adjacent to each other in the second direction DR2. Unlike the shown example, the second channel region CHR2 may be disposed between the first protruding insulation pattern 110 and the second protruding insulation pattern 210. For example, the first protruding insulation patterns 110 may have the same height (e.g., thickness in a vertical direction) and the second protruding insulation pattern 210 may have a different height from the first protruding insulation patterns 110.

A distance by which the first channel region CHR1 is spaced from the first protruding insulation pattern 110 in the second direction DR2 may be equal to a distance by which the first channel region CHR1 is spaced from the second protruding insulation pattern 210 in the second direction DR2.

The first protruding insulation pattern 110 and the second protruding insulation pattern 210 may include a material having an etching selectivity with respect to the field insulating film 105. When the field insulating film 105 includes silicon oxide, the first protruding insulation pattern 110 and the second protruding insulation pattern 210 may include at least one of silicon nitride or silicon oxynitride.

A height H11 of the first protruding insulation pattern 110 in the third direction DR3 may be different from a height H21 of the second protruding insulation pattern 210 in the third direction DR3. For example, the height H11 of the first protruding insulation pattern 110 in the third direction DR3 may be greater than the height H21 of the second protruding insulation pattern 210 in the third direction DR3. For example, the height H11 of the first protruding insulation pattern 110 may be measured at the center of the width of the first protruding insulation pattern 110 in the second direction DR2, and the height H21 of the second protruding insulation pattern 210 may be measured at the center of the width of the second protruding insulation pattern 210 in the second direction DR2. Throughout the description, a height may be a thickness of an element in a vertical direction and/or a distance in the vertical direction depending on the context.

Taking the first protruding insulation pattern 110 as an example, the first protruding insulation pattern 110 may include a first portion 110_P1 and a second portion 110_P2. The first portion 110_P1 of the first protruding insulation pattern may overlap a gate structure GS in the third direction DR3. The second portion 110_P2 of the first protruding insulation pattern may be disposed between the first source/drain pattern 150 and the second source/drain pattern 250. In FIGS. 4 and 5, the first portion 110_P1 of the first protruding insulation pattern may overlap the gate electrode 120 in the second direction DR2, and the second portion 110_P2 of the first protruding insulation pattern may overlap the first source/drain pattern 150 in the second direction DR2.

The height H11 of the first protruding insulation pattern 110 in the third direction DR3 at the first portion 110_P1 of the first protruding insulation pattern may be different from a height H12 of the first protruding insulation pattern 110 at the second portion 110_P2 of the first protruding insulation pattern. For example, the height H11 of the first protruding insulation pattern 110 at the first portion 110_P1 of the first protruding insulation pattern may be greater than the height H12 of the first protruding insulation pattern 110 at the second portion 110_P2 of the first protruding insulation pattern. During the formation of the first source/drain pattern 150 and/or the second source/drain pattern 250, the second portion 110_P2 of the first protruding insulation pattern may be etched.

The height H11 of the first protruding insulation pattern 110 may be the height of the first protruding insulation pattern 110 in the third direction DR3 at the first portion 110_P1 of the first protruding insulation pattern. Unlike that shown in FIG. 5, the second protruding insulation pattern 210 may not be disposed in a portion that overlaps the first source/drain pattern 150 and the second source/drain pattern 250 in the second direction DR2. During the formation of the first source/drain pattern 150 and/or the second source/drain pattern 250, the second protruding insulation pattern 210 located in a portion that overlaps the first source/drain pattern 150 and the second source/drain pattern 250 in the second direction DR2 may be etched.

A width of the first protruding insulation pattern 110 in the second direction DR2 at the first portion 110_P1 of the first protruding insulation pattern may be greater than or equal to a width of the first protruding insulation pattern 110 in the second direction DR2 at the second portion 110_P2 of the first protruding insulation pattern.

A plurality of gate structures GS may be disposed on the first substrate 100. Each gate structure GS may be disposed on the first side 105_US of the field insulating film. The gate structures GS may extend in the second direction DR2. The gate structures GS may be adjacent to each other in the first direction DR1. The gate structures GS may be spaced apart from each other in the first direction DR1.

The gate structure GS may be disposed on the first protruding insulation pattern 110, the second protruding insulation pattern 210, the first channel region CHR1, and the second channel region CHR2. The gate structure GS may be disposed on the first lower pattern BP1 and the second lower pattern BP2. The gate structure GS may be in contact with the first protruding insulation pattern 110 and the second protruding insulation pattern 210.

In the semiconductor device according to some embodiments, the gate structure GS may enclose the first channel region CHR1, e.g., in a cross-sectional view. The gate structure GS may enclose the first channel pattern CH1, e.g., in the cross-sectional view. The gate structure GS may enclose the second channel pattern/region CH2/CHR2, e.g., in the cross-sectional view. The gate structure GS may be disposed on a bottom side CH1_BS of the first channel pattern and an upper side CH1_US of the first channel pattern.

The gate structure GS may include a gate electrode 120 and a gate insulating film 130.

The gate electrode 120 may be disposed on a first side 105_US of the field insulating film. The gate electrode 120 may extend in the second direction DR2.

The gate electrode 120 may be disposed on the first protruding insulation pattern 110 and the second protruding insulation pattern 210. The gate electrode 120 may be disposed on the first channel region CHR1 and the second channel region CHR2. In the cross-sectional view, the gate electrode 120 may enclose the first channel pattern CH1 and the second channel pattern CH2.

The gate electrode 120 may include a body gate electrode 120BD and a connecting gate electrode 120BR. The body gate electrode 120BD and the connecting gate electrode 120BR may be disposed alternately in the second direction DR2. The body gate electrode 120BD may be disposed between two connecting gate electrodes 120BR adjacent to each other in the second direction DR2. The connecting gate electrode 120BR may be disposed between two body gate electrodes 120BD adjacent to each other in the second direction DR2.

The body gate electrode 120BD may be disposed on the first channel region CHR1 and the second channel region CHR2. The body gate electrode 120BD may be disposed on the first side wall CHR_SW1 of the first channel region and the second side wall CHR_SW2 of the first channel region. In the semiconductor device according to some embodiments, the body gate electrode 120BD may be a part of the gate electrode 120 that encloses the first channel region CHR1 and the second channel region CHR2. The body gate electrode 120BD may be disposed on the upper side CH1_US of the first channel region and the bottom side CH1_BS of the first channel region.

The body gate electrode 120BD may be disposed between the first protruding insulation pattern 110 and the second protruding insulation pattern 210 that are adjacent to each other in the second direction DR2, or between the first protruding insulation patterns 110 adjacent to each other in the second direction DR2. Although not shown, the body gate electrode 120BD may be disposed between the second protruding insulation patterns 210 adjacent to each other in the second direction DR2.

The body gate electrode 120BD may not overlap the first protruding insulation pattern 110 and the second protruding insulation pattern 210 in the third direction DR3. The body gate electrode 120BD may be a portion of the gate electrode 120 that does not overlap the first protruding insulation pattern 110 and the second protruding insulation pattern 210 in the third direction DR3.

The connecting gate electrode 120BR may include a first connecting gate electrode 120BR1 and a second connecting gate electrode 120BR2. Each of the first connecting gate electrode 120BR1 and the second connecting gate electrode 120BR2 may extend/protrude from the body gate electrode 120BD in the second direction DR2. The first connecting gate electrode 120BR1 and/or the second connecting gate electrode 120BR2 may connect (e.g., electrically connect) the body gate electrodes 120BD adjacent to each other in the second direction DR2. The first connecting gate electrode 120BR1 and the second connecting gate electrode 120BR2 may be directly/integrally connected to the body gate electrode 120BD, e.g., as one body without detectable boundaries.

As an example, the body gate electrode 120BD may be disposed between the first connecting gate electrode 120BR1 and the second connecting gate electrode 120BR2. As another example, the body gate electrode 120BD may be disposed between the first connecting gate electrodes 120BR1 adjacent to each other in the second direction DR2. As another example, although not shown, the body gate electrode 120BD may be disposed between the second connecting gate electrodes 120BR2 adjacent to each other in the second direction DR2.

The first connecting gate electrode 120BR1 may be disposed on the first protruding insulation pattern 110. The first connecting gate electrode 120BR1 may overlap the first protruding insulation pattern 110 in the third direction DR3. The first protruding insulation pattern 110 may be disposed between the first connecting gate electrode 120BR1 and the field insulating film 105. For example, the first connecting gate electrode 120BR1 may be disposed on the first side wall CHR_SW1 of the first channel region.

The second connecting gate electrode 120BR2 may be disposed on the second protruding insulation pattern 210. The second connecting gate electrode 120BR2 may overlap the second protruding insulation pattern 210 in the third direction DR3. The second protruding insulation pattern 210 may be disposed between the second connecting gate electrode 120BR2 and the field insulating film 105. For example, the second connecting gate electrode 120BR2 may be disposed on the second side wall CHR_SW2 of the first channel region.

The body gate electrode 120BD may include a first side 120BD_US and a second side 120BD_BS that are opposite to each other in the third direction DR3. The second side 120BD_BS of the body gate electrode may face the field insulating film 105. The first side 120BD_US of the body gate electrode may be an upper/top side/surface of the body gate electrode 120BD. The second side 120BD_BS of the body gate electrode may be a lower/bottom side/surface of the body gate electrode 120BD. For example, the first side 120BD_US of the body gate electrode may be an upper/top side/surface of the gate electrode 120, and the second side 120BD_BS of the body gate electrode may be a lower/bottom side/surface of the gate electrode 120.

The connecting gate electrode 120BR may include a first side 120BR_US and a second side 120BR_BS that are opposite to each other in the third direction DR3. The second side 120BR_BS of the connecting gate electrode may face the field insulating film 105. The first side 120BR_US of the connecting gate electrode may be an upper/top side/surface of the connecting gate electrode 120BR. The second side 120BR_BS of the connecting gate electrode may be a lower/bottom side/surface of the connecting gate electrode 120BR.

A height H31 from the second side 105_BS of the field insulating film to the second side 120BR_BS of the connecting gate electrode at the first connecting gate electrode 120BR1 may be different from a height H33 from the second side 105_BS of the field insulating film to the second side 120 BR_BS of the connecting gate electrode at the second connecting gate electrode 120BR2. For example, the height H31 from the second side 105_BS of the field insulating film to the second side 120BR_BS of the connecting gate electrode at the first connecting gate electrode 120BR1 may be greater than the height H33 from the second side 105_BS of the field insulating film to the second side 120BR_BS of the connecting gate electrode at the second connecting gate electrode 120BR2.

A height H32 from the second side 105_BS of the field insulating film to the first side 120BR_US of the connecting gate electrode at the first connecting gate electrode 120BR1 may be different from a height H34 from the second side 105_BS of the field insulating film to the first side 120BR_US of the connecting gate electrode at the second connecting gate electrode 120BR2. The height H32 from the second side 105_BS of the field insulating film to the first side 120BR_US of the connecting gate electrode at the first connecting gate electrode 120BR1 may be greater than the height H34 from the second side 105_BS of the field insulating film to the first side 120BR_US of the connecting gate electrode at the second connecting gate electrode 120BR2.

In the first connecting gate electrode 120BR1 as an example, the height H31 of the first side 120BR_US of the connecting gate electrode and the height H32 of the second side 120BR_BS of the connecting gate electrode may be measured near or at the center of the width of the first protruding insulation pattern 110 in the second direction DR2. When the front gate contact 175 is disposed near or at the center of the width of the first protruding insulation pattern 110 in the second direction DR2, the height H31 of the first side 120BR_US of the connecting gate electrode may be measured at a portion in which the front gate contact 175 is not landed, e.g., right next to the front gate contact 175 or at a point where the front gate contact 175, the gate insulating film 130, and the gate electrode 120 meet each other.

A height (H32-H31) of the first connecting gate electrode 120BR1 in the third direction DR3 may be equal to a height (H34-H33) of the second connecting gate electrode 120BR2 in the third direction DR3.

A height H4 of the body gate electrode 120BD in the third direction DR3 is greater than the height (H32-H31) of the first connecting gate electrode 120BR1 in the third direction DR3. The height H4 of the body gate electrode 120BD in the third direction DR3 is greater than the height (H34-H33) of the second connecting gate electrode 120BR2 in the third direction DR3.

A thickness t11 of the body gate electrode 120BD in the second direction DR2 on the first side wall CHR_SW1 of the first channel region may be equal to a thickness t12 of the body gate electrode 120BD in the second direction DR2 on the second side wall CHR_SW2 of the first channel region. The thickness t11 of the body gate electrode 120BD in the second direction DR2 on the first side wall CHR_SW1 of the first channel region may be equal to the height (H32-H31) of the first connecting gate electrode 120BR1 in the third direction DR3.

The gate electrode 120 may include at least one of a metal, a conductive metal nitride, a metal silicide, a doped semiconductor material, a conductive metal oxide, a conductive metal oxynitride, a conductive metal carbide, a conductive metal carbonitride or a combination thereof. The gate electrode 120 may include, for example, but is not limited to at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (NiPt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V) or combinations thereof. The conductive metal oxide and the conductive metal oxynitride may include, but are not limited to, an oxidized form of the aforementioned materials.

As an example, the body gate electrode 120BD and the connecting gate electrode 120BR may include the same conductive material. As another example, the connecting gate electrode 120BR may include a conductive material different from that of the body gate electrode 120BD. In such a case, the connecting gate electrode 120BR may include a material having a lower resistivity than the body gate electrode 120BD.

The gate electrode 120 may be disposed on both sides of a first source/drain pattern 150, which will be described below. Two of the gate structures GS may be disposed on both sides of the first source/drain pattern 150 in the first direction DR1, respectively.

As an example, all the gate electrodes 120 disposed on both sides of the first source/drain pattern 150 may be normal gate electrodes used as gates (gate electrodes) of transistors. As another example, the gate electrodes 120 disposed on one side of the first source/drain pattern 150 may be used as a gate of a transistor, but the gate electrode 120 disposed on the other side of the first source/drain pattern 150 may be a dummy gate electrode.

Although not shown, the gate electrodes 120 may be disposed on both sides of the second source/drain pattern 250 to be described below. The gate structures GS may be disposed on both sides of the second source/drain pattern 250 in the first direction DR1, respectively.

Because a height at which the first connecting gate electrode 120BR1 is disposed differs from a height at which the second connecting gate electrode 120BR2 is disposed, the distance between the gate electrode 120 and the front source/drain contacts 170 and 270 may be different/adjusted. Accordingly, a RC delay or the like of the gate electrode 120 and the front source/drain contacts 170 and 270 can be reduced, e.g., by adjusting the heights of the first and second protruding insulation patterns 110 and 120. The performance and reliability of the semiconductor device can be improved, accordingly.

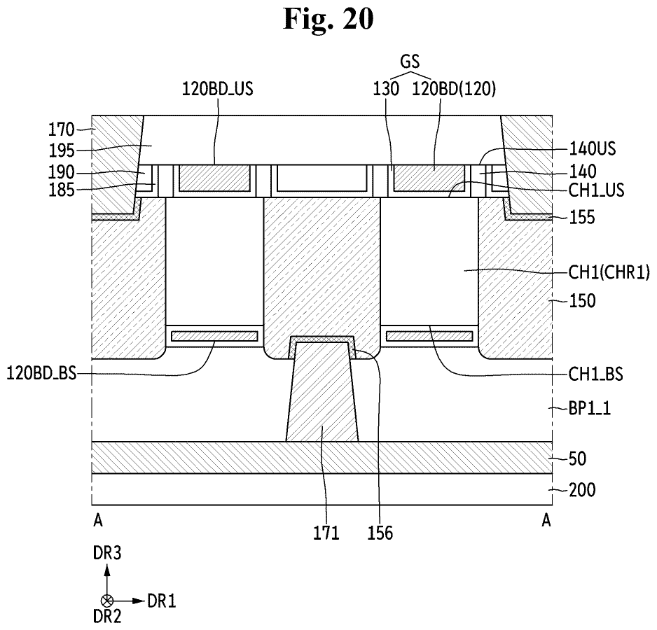

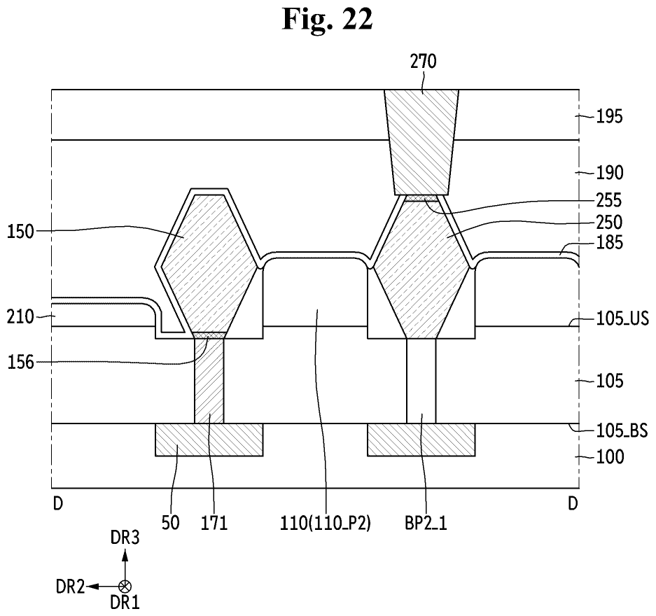

In addition, since the distance between the gate electrode 120 and a back source/drain contact (171 of FIGS. 20 and 22) is adjusted (e.g., by the first and second protruding insulation patterns 110 and 120), the RC delay or the like of the gate electrode 120 and a back source/drain contact 171 can be reduced.

The gate insulating film 130 may be disposed between the gate electrode 120 and the first protruding insulation pattern 110, and between the gate electrode 120 and the second protruding insulation pattern 210. The gate insulating film 130 may be disposed between the gate electrode 120 and the first channel region CHR1, and between the gate electrode 120 and the second channel region CHR2.

The gate insulating film 130 may extend along the profile of the first protruding insulation pattern 110, the profile of the second protruding insulation pattern 210, and the first side 105_US of the field insulating film. The gate insulating film 130 may extend along the first side 120BR_US of the connecting gate electrode and the second side 120BR_BS of the connecting gate electrode.

The gate insulating film 130 may extend along the second side 120BD_BS of the body gate electrode. The gate insulating film 130 does not extend along the first side 120BD_US of the body gate electrode. For example, the gate insulating film 130 is not formed along/on the upper side 120BD_US of the body gate electrode.

The gate insulating film 130 may include silicon oxide, silicon oxynitride, silicon nitride or a high dielectric constant material having a dielectric constant higher than silicon oxide. The high dielectric constant material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide or lead zinc niobate.

Although the gate insulating film 130 is shown as being a single film, this is only for convenience of explanation, and the embodiment is not limited thereto. For example, the gate insulating film 130 may include a plurality of films/layers. As an example, the gate insulating film 130 may include an interfacial film and a high dielectric constant insulating film disposed between the first channel region CHR1 and the gate electrode 120. For example, the interfacial film may not be formed along the profile of the first side 105_US of the field insulating film.

A semiconductor device according to some embodiments may include an NC (Negative Capacitance) FET that uses a negative capacitor. For example, the gate insulating film 130 may include a ferroelectric material film having ferroelectric properties, and a paraelectric material film having paraelectric properties.

The ferroelectric material film may have a negative capacitance, and the paraelectric material film may have a positive capacitance. For example, when two or more capacitors are connected in series and the capacitance of each capacitor has a positive value, the overall capacitances decrease from the capacitance of each of the individual capacitors. On the other hand, when at least one of the capacitances of two or more capacitors connected in series has a negative value, the overall capacitances may be greater than an absolute value of each of the two or more capacitances, while having a positive value.

When the ferroelectric material film having the negative capacitance and the paraelectric material film having the positive capacitance are connected in series, the overall capacitance values of the ferroelectric material film and the paraelectric material film connected in series may increase. By the use of the increased overall capacitance value, a transistor including the ferroelectric material film may have a subthreshold swing (SS) below 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide or lead zirconium titanium oxide. Here, as an example, the hafnium zirconium oxide may be a material obtained by doping hafnium oxide with zirconium (Zr). As another example, the hafnium zirconium oxide may be a compound of hafnium (Hf), zirconium (Zr), and oxygen (O).

The ferroelectric material film may further include a dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr) or tin (Sn). The type of dopant included in the ferroelectric material film may vary, depending on which type of ferroelectric material is included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and yttrium (Y).

When the dopant is aluminum (Al), the ferroelectric material film may include 3 to 8 at % (atomic %) aluminum. Here, a ratio of the dopant may be a ratio of aluminum to the sum of hafnium and aluminum.

When the dopant is silicon (Si), the ferroelectric material film may include 2 to 10 at % silicon. When the dopant is yttrium (Y), the ferroelectric material film may include 2 to 10 at % yttrium. When the dopant is gadolinium (Gd), the ferroelectric material film may include 1 to 7 at % gadolinium. When the dopant is zirconium (Zr), the ferroelectric material film may include 50 to 80 at % zirconium.

The paraelectric material film may have paraelectric properties. The paraelectric material film may include at least one of, for example, a silicon oxide or a metal oxide having a high dielectric constant. The metal oxide included in the paraelectric material film may include, for example, but is not limited to, at least one of hafnium oxide, zirconium oxide, or aluminum oxide.

The ferroelectric material film and the paraelectric material film may include the same material. The ferroelectric material film has the ferroelectric properties, but the paraelectric material film may not have the ferroelectric properties. For example, when the ferroelectric material film and the paraelectric material film include hafnium oxide, a crystal structure of hafnium oxide included in the ferroelectric material film differs from a crystal structure of hafnium oxide included in the paraelectric material film.

The ferroelectric material film may have a thickness having the ferroelectric properties. The thickness of the ferroelectric material film may be, for example, but is not limited to, 0.5 to 10 nm. Since a critical thickness that exhibits the ferroelectric properties may vary for each ferroelectric material, the thickness of the ferroelectric material film may vary depending on the ferroelectric material.

As an example, the gate insulating film 130 may include one ferroelectric material film. As another example, the gate insulating film 130 may include a plurality of ferroelectric material films spaced apart from each other. Each gate insulating film 130 may have a stacked film structure in which the plurality of ferroelectric material films and the plurality of paraelectric material films are stacked alternately.

A gate spacer 140 may be disposed on the first side 105_US of the field insulating film. The gate spacer 140 may be disposed on the first protruding insulation pattern 110. In the cross-sectional view such as FIG. 3, the first protruding insulation pattern 110 may be disposed between the gate spacer 140 and the field insulating film 105.

The gate spacer 140 may be disposed on a side wall of the gate electrode 120. The gate spacer 140 may extend in the second direction DR2.

From the first side 105_US of the field insulating film, an upper side 140US of the gate spacer may be farther than an upper side 120BR_US of the connecting gate electrode. For example, the upper side 140US of the gate spacer may be higher than the upper side 120BR_US of the connecting gate electrode. The upper side 140US of the gate spacer 140 may be a top/upper surface of the gate spacer 140. In the semiconductor device according to some embodiments, the upper side 140US of the gate spacer may be disposed in the same plane as the first side 120BD_US of the body gate electrode.

The gate spacer 140 may include, for example, silicon nitride, silicon oxynitride, silicon oxide, silicon oxycarbonitride, silicon boronitride, silicon oxyboronitride, silicon oxycarbide or a combination thereof.

The first source/drain pattern 150 may be disposed on the first substrate 100. The first source/drain pattern 150 may be disposed on the first lower pattern BP1. The first source/drain pattern 150 may be electrically connected to the first channel region CHR1.

The first source/drain pattern 150 may be disposed between two gate structures GS. The first source/drain pattern 150 may be disposed on at least one side of a gate structure GS. The first source/drain pattern 150 may be disposed on a side face/surface of the gate electrode 120. For example, first source/drain patterns 150 may be disposed on both sides of the gate structure GS. Unlike the shown example, the first source/drain pattern 150 is disposed on one side of the gate structure GS, and may not be disposed on the other side of the gate structure GS.

The second source/drain pattern 250 may be disposed on the first substrate 100. The second source/drain pattern 250 may be disposed on the second lower pattern BP2. Although not shown, the second source/drain pattern 250 may be electrically connected to the second channel region CHR2.

The first source/drain pattern 150 may be a source/drain of a transistor that uses the first channel region CHR1 as a channel. The second source/drain pattern 250 may be a source/drain of a transistor that uses the second channel region CHR2 as a channel.

Each of the first source/drain pattern 150 and the second source/drain pattern 250 may include or may be an epitaxial pattern. The first source/drain pattern 150 and the second source/drain pattern 250 may include, for example, a semiconductor material.

The first source/drain pattern 150 and the second source/drain pattern 250 may include n-type impurities or p-type impurities. The n-type impurities may include at least one of phosphorus (P), arsenic (As), antimony (Sb) or bismuth (Bi). The p-type impurities may include at least one of boron (B) or gallium (Ga).

A source/drain etching stop film 185 may extend along the profile of the first protruding insulation pattern 110 and the profile of the second protruding insulation pattern 210. The source/drain etching stop film 185 may extend along side walls/surfaces of the gate structure GS, side walls/surfaces of the first source/drain pattern 150, and side walls/surfaces of the second source/drain pattern 250.

The source/drain etching stop film 185 may include a material having an etching selectivity with respect to a first interlayer insulating film 190 to be described below. The source/drain etching stop film 185 may include, for example, at least one of silicon nitride, silicon oxynitride, silicon oxycarbonitride, silicon boronitride, silicon oxyboronitride, silicon oxycarbide or combinations thereof. Unlike the shown example, the source/drain etching stop film 185 may not be formed.

A first interlayer insulating film 190 may be disposed on the source/drain etching stop film 185. The first interlayer insulating film 190 may cover the first source/drain pattern 150 and the second source/drain pattern 250. The first interlayer insulating film 190 may not cover the upper side 140US of the gate spacer.

The first interlayer insulating film 190 may include at least one of, for example, silicon oxide, silicon nitride, silicon oxynitride, and a low dielectric constant material. The dielectric constant of the low dielectric constant material may have a value smaller than 3.9, which is the dielectric constant of silicon oxide. The low dielectric constant material may include, for example, but is not limited to, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica or combinations thereof.

A second interlayer insulating film 195 may be disposed on the first interlayer insulating film 190 and the gate electrode 120. A part of the second interlayer insulating film 195 may be disposed between the gate spacers 140 adjacent to each other in the first direction DR1.

For example, the second interlayer insulating film 195 may be in contact with the upper side 140US of the gate spacer. The second interlayer insulating film 195 may be in contact with the first side 120BD_US of the body gate electrode.

The second interlayer insulating film 195 may include a gate separation region CT_R. The gate separation region CT_R may separate (e.g., be disposed between) the gate electrodes 120 adjacent to each other in the second direction DR2.

The gate separation region CT_R may be located on the first protruding insulation pattern 110. The gate separation region CT_R may be formed in the connecting gate electrode 120BR. Although not shown, the gate separation region CT_R may be located on the second protruding insulation pattern 210. The gate insulating film 130 may extend along a boundary between the gate separation region CT_R and the gate electrode 120.

The second interlayer insulating film 195 may include, for example, at least one of silicon oxide, silicon nitride, silicon oxynitride, and a low dielectric constant material.

A first front source/drain contact 170 may be disposed on the first source/drain pattern 150. The first front source/drain contact 170 may be electrically connected to and/or contact the first source/drain pattern 150.

A second front source/drain contact 270 may be disposed on the second source/drain pattern 250. The second front source/drain contact 270 may be electrically connected to and/or contact the second source/drain pattern 250.

Unlike the shown example, a part of the first front source/drain contact 170 may be directly connected to the second front source/drain contact 270. For example, a connecting source/drain contact simultaneously connected to the first source/drain pattern 150 and the second source/drain pattern 250 may be disposed on the first side 105_US of the field insulating film.

The first front source/drain contact 170 and the second front source/drain contact 270 may be disposed inside the first interlayer insulating film 190 and the second interlayer insulating film 195. The first front source/drain contact 170 and the second front source/drain contact 270 may penetrate the source/drain etch stop film 185.

Although the first front source/drain contact 170 and the second front source/drain contact 270 are shown to have a single conductive film structure, the embodiment is not limited thereto. Unlike the shown example, the first front source/drain contact 170 and the second front source/drain contact 270 may have multiple conductive film structures including a barrier film and a plug film. The first front source/drain contact 170 and the second front source/drain contact 270 may include at least one of, for example, a metal, a conductive metal nitride, a conductive metal carbide, a conductive metal oxide, a conductive metal carbonitride or a two-dimensional material (2D dimensional).

The two-dimensional material (2D material) may include a two-dimensional allotrope or a two-dimensional compound, and may include, for example, but is not limited to, at least one of graphene, boron nitride (BN), molybdenum sulfide, molybdenum selenide, tungsten sulfide, tungsten selenide, and tantalum sulfide. The above-mentioned 2D materials are only listed as an example, and the 2D materials that may be included in the semiconductor device of the present disclosure are not limited by the above-mentioned materials.

A first front contact silicide film 155 may be disposed between the first front source/drain contact 170 and the first source/drain pattern 150. A second front contact silicide film 255 may be disposed between the second front source/drain contact 270 and the second source/drain pattern 250. Each of the first front contact silicide film 155 and the second front contact silicide film 255 may include, for example, a metal silicide material.

The front gate contact 175 may be disposed in the second interlayer insulating film 195. The front gate contact 175 may penetrate the second interlayer insulating film 195, and be electrically connected to and/or contact the gate electrode 120.

The front gate contact 175 may be disposed on the gate electrode 120. For example, the front gate contact 175 may be electrically connected to and/or contact the connecting gate electrode 120BR. Unlike the shown example, the front gate contact 175 may be disposed on and/or contact the body gate electrode 120BD.

Although the front gate contact 175 is shown to have a single conductive film structure, the embodiment is not limited thereto. The front gate contact 175 may include at least one of, for example, a metal, a conductive metal nitride, a conductive metal carbide, a conductive metal oxide, a conductive metal carbonitride or a two-dimensional material (2D material).

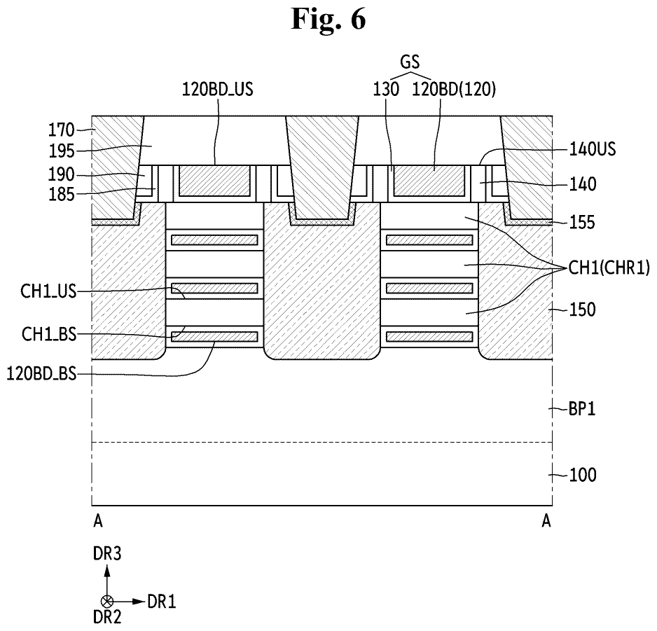

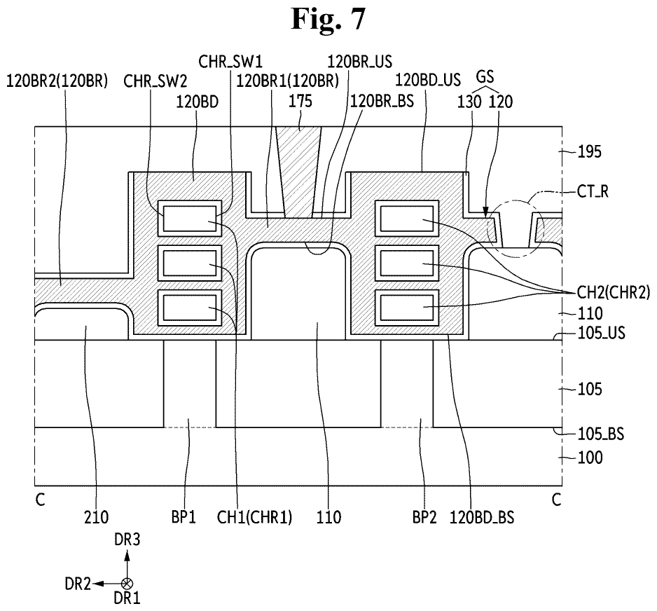

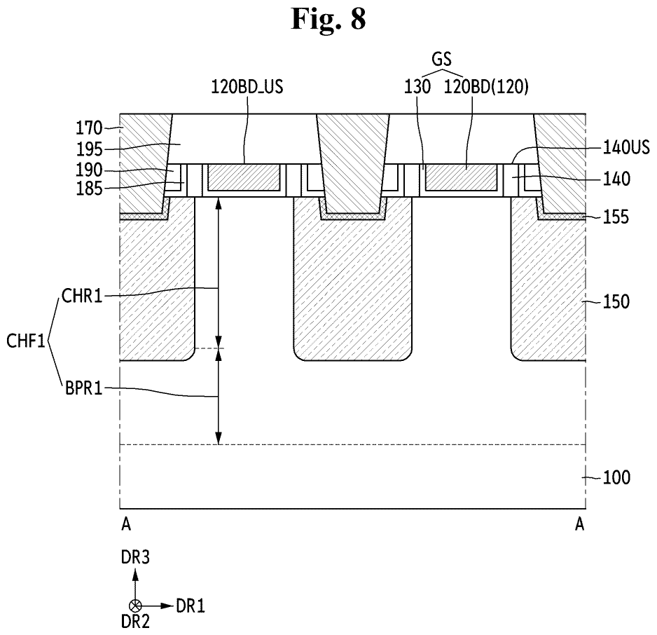

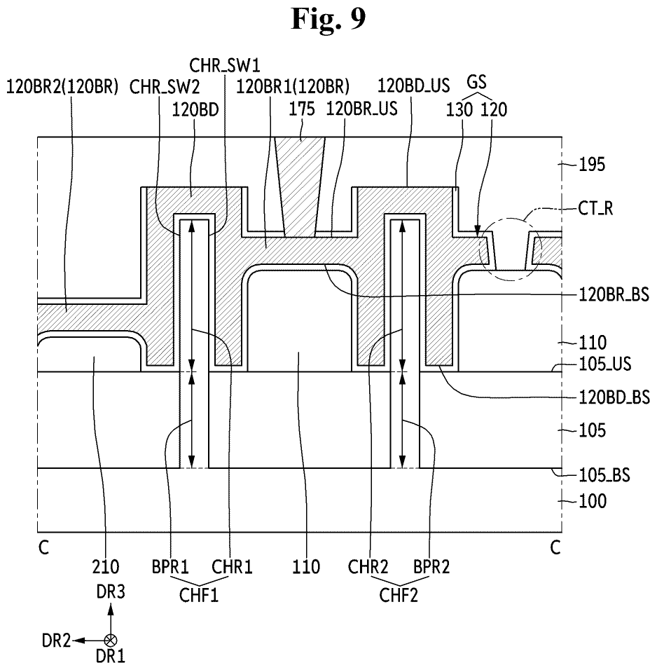

FIGS. 6 and 7 are diagrams for explaining a semiconductor device according to some embodiments. FIGS. 8 and 9 are diagrams for explaining a semiconductor device according to some embodiments. For convenience of explanation, with respect to embodiments illustrated in FIGS. 6, 7, 8 and 9, differences from those explained using FIGS. 1 to 5 will be mainly explained.

Referring to FIGS. 6 and 7, in the semiconductor device according to some embodiments, the first channel region CHR1 may include a plurality of first channel patterns CH1 spaced apart from each other in the third direction DR3.

The second channel region CHR2 may include a plurality of second channel patterns CH2 spaced apart from each other in the third direction DR3.

The plurality of first channel patterns CH1 may be disposed on the first lower pattern BP1. The plurality of first channel patterns CH1 may be spaced apart from the first lower pattern BP1 in the third direction DR3. Each first channel pattern CH1 may be spaced apart from the other first channel patterns CH1 in the third direction DR3.

The plurality of second channel patterns CH2 may be disposed on the second lower pattern BP2. The plurality of second channel patterns CH2 may be spaced apart from the second lower pattern BP2 in the third direction DR3. Each second channel pattern CH2 may be spaced apart from the other second channel patterns CH2 in the third direction DR3.

Although three first channel patterns CH1 and three second channel patterns CH2 are shown in FIG. 6 as being arranged/disposed in the third direction DR3, respectively, this is only for convenience of explanation, and the embodiment is not limited thereto.

For example, the bottom side CH1_BS of the lowermost first channel pattern CH1 may be the bottom side of the first channel region CHR1. The upper side CH1_US of the uppermost first channel pattern CH1 may be the upper side of the first channel region CHR1.

The first side wall of the first channel region CHR1 may include the first side walls CHR_SW1 of first channel patterns arranged in the third direction DR3. The second side wall of the first channel region CHR1 may include the second side walls CHR_SW2 of the first channel patterns arranged in the third direction DR3.

In a cross-sectional view as shown in FIG. 6, a body gate electrode 120BD may enclose each of the first channel patterns CH1. In the cross-sectional view, a body gate electrode 120BD may enclose each of the second channel patterns CH2.

Referring to FIGS. 8 and 9, the semiconductor device according to some embodiments may include a first fin-shaped pattern CHF1 and a second fin-shaped pattern CHF2 that protrude from the first substrate 100.

The first fin-shaped pattern CHF1 may be disposed between the first protruding insulation pattern 110 and the second protruding insulation pattern 210. The first fin-shaped pattern CHF1 may include a first lower region BPR1 and a first channel region CHR1. The first channel region CHR1 may be connected directly/integrally to the first lower region BPR1, e.g., as one body without a detectable boundary between the first channel region CHR1 and the first lower region BPR1.

The first lower region BPR1 may be a portion of the first fin-shaped pattern CHF1 that is in contact with the field insulating film 105. For example, the first lower region BPR1 may be a portion of the first fin-shaped pattern CHF1 horizontally overlapping the field insulating film 105. The first channel region CHR1 may be a portion of the first fin-shaped pattern CHF1 that is not in contact with the field insulating film 105. For example, the first channel region CHR1 may be a portion of the first fin-shaped pattern CHF1 that does not horizontally overlap the field insulating film 105. For example, the field insulating film 105 may not cover the first side wall CHR_SW1 of the first channel region and the second side wall CHR_SW2 of the first channel region.

The second fin-shaped pattern CHF2 may be disposed between the first protruding insulation patterns 110 adjacent to each other in the second direction DR2. The second fin-shaped pattern CHF2 may include a second lower region BPR2 and a second channel region CHR2. The second channel region CHR2 may be connected directly/integrally to the second lower region BPR2, e.g., as one body without a detectable boundary between the second channel region CHR2 and the second lower region BPR2.

The second lower region BPR2 may be a portion of the second fin-shaped pattern CHF2 that is in contact with the field insulating film 105. For example, the second lower region BPR2 may be a portion of the second fin-shaped pattern CHF2 horizontally overlapping the field insulating film 105. The second channel region CHR2 may be a portion of the second fin-shaped pattern CHF2 that is not in contact with the field insulating film 105. For example, the second channel region CHR2 may be a portion of the second fin-shaped pattern CHF2 that does not horizontally overlap the field insulating film 105.

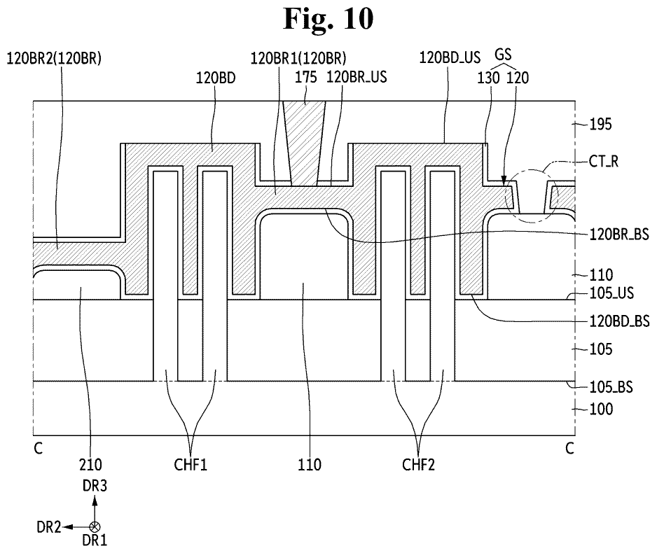

FIG. 10 is a diagram for explaining a semiconductor device according to some embodiments. For convenience of explanation, with respect to embodiments illustrated in FIG. 10, differences from those explained using FIG. 8 and FIG. 9 will be mainly explained.

Referring to FIG. 10, in the semiconductor device according to some embodiments, a plurality of first fin-shaped patterns CHF1 may be disposed between the first protruding insulation pattern 110 and the second protruding insulation pattern 210, e.g., adjacent to each other, e.g., closest to each other in the second direction.

A plurality of second fin-shaped patterns CHF2 may be disposed between the first protruding insulation patterns 110 adjacent to each other in the second direction DR2.

The connecting gate electrode 120BR is not disposed between the above described first fin-shaped patterns CHF1 adjacent to each other in the second direction DR2. The connecting gate electrode 120BR is not disposed between the above described second fin-shaped patterns CHF2 adjacent to each other in the second direction DR2.

The first fin-shaped pattern CHF1 will be explained as an example. The plurality of first fin-shaped patterns CHF1 may include a first sub fin-shaped pattern and a second sub fin-shaped pattern that are disposed at the outermost corner. Each of the first sub fin-shaped pattern and the second sub fin-shaped pattern may include a first side wall and a second side wall that are opposite to each other in the second direction DR2. The second side wall of the first sub fin-shaped pattern may face the second side wall of the second sub fin-shaped pattern. In this case, the first side wall of the first sub fin-shaped pattern may include the first side wall (CHR_SW1 of FIG. 9) of the first channel region. The first side wall of the second sub fin-shaped pattern may include the second side wall (CHR_SW2 of FIG. 9) of the first channel region.

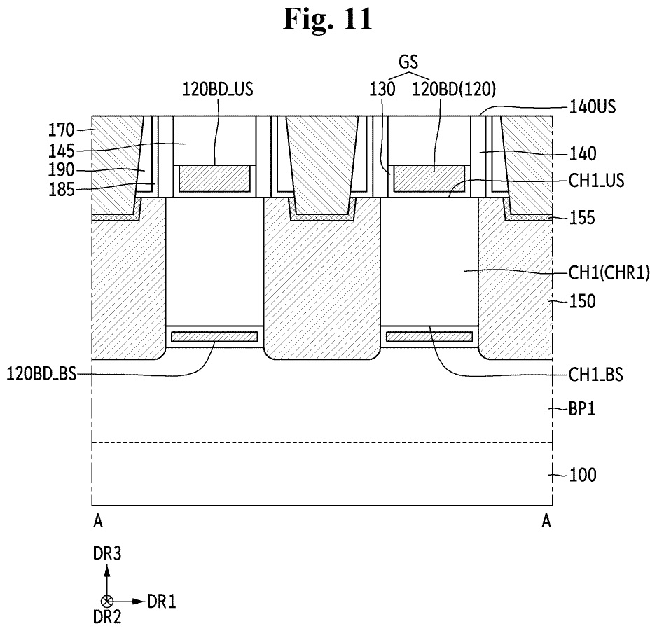

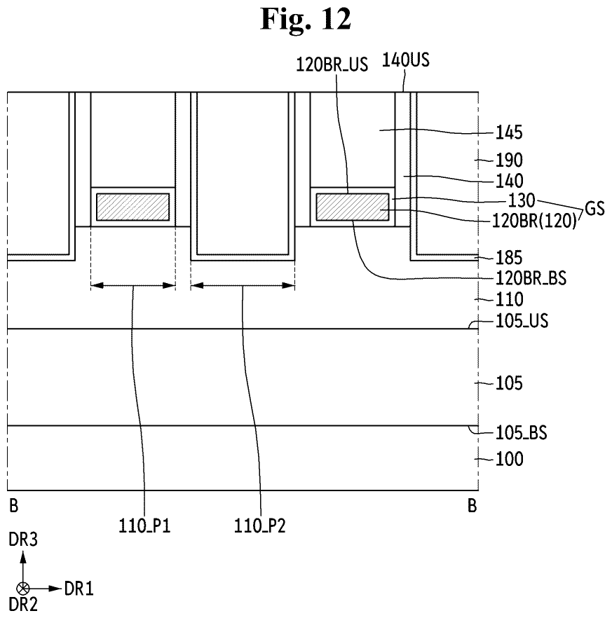

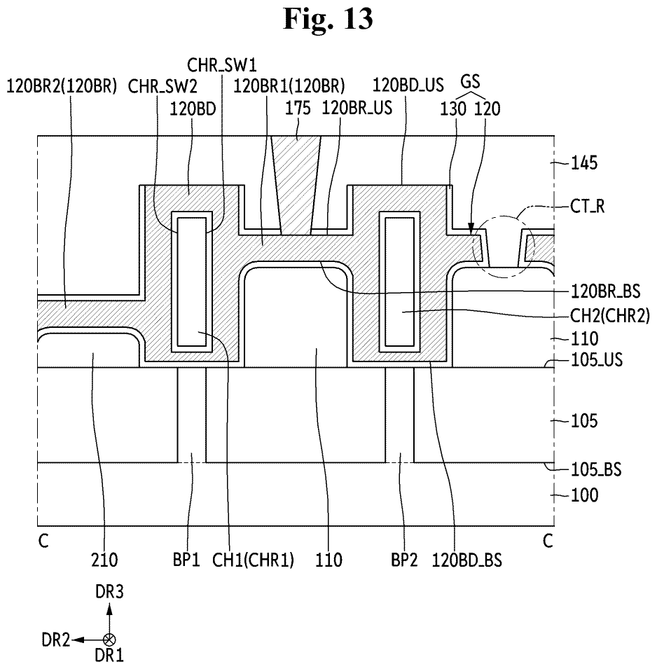

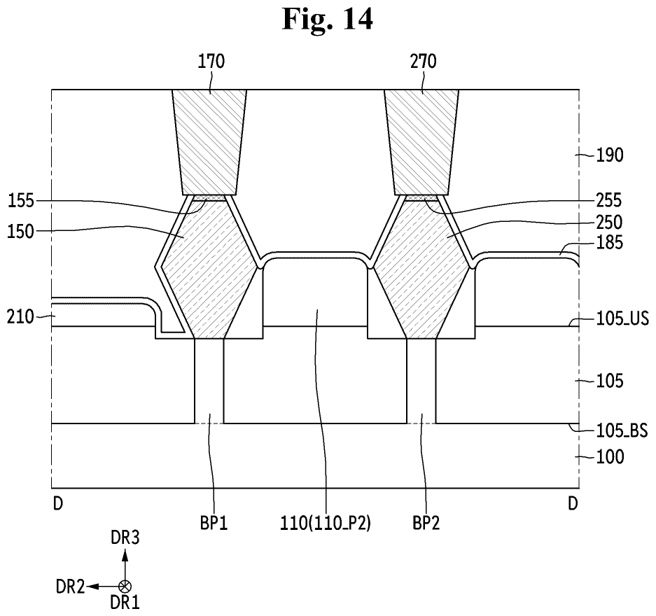

FIGS. 11 to 14 are diagrams for explaining a semiconductor device according to some embodiments. For convenience of explanation, with respect to embodiments illustrated in FIGS. 11 to 14, differences from those described using FIGS. 1 to 5 will be mainly explained.

Referring to FIGS. 11 to 14, the semiconductor device according to some embodiments may include a gate capping pattern 145.

The gate capping pattern 145 may be disposed between the gate spacers 140 adjacent to each other in the first direction DR1, e.g., between gate spacers 140 disposed on both sides of a gate structures GS. The gate capping pattern 145 may be disposed on the gate electrode 120. The gate capping pattern 145 may be in contact with the first side 120BD_US of the body gate electrode.

The gate capping pattern 145 may include a gate separation region CT_R. An upper side of the gate capping pattern 145 may be placed on the same plane as the upper side 140US of the gate spacer and the upper side of the first front source/drain contact 170. The upper side of the gate capping pattern 145 may be a top/upper surface of the gate capping pattern 145. The gate capping pattern 145 may not be disposed on and may not contact the upper side/surface of the first interlayer insulating film 190.

The gate capping pattern 145 may include, for example, silicon nitride, silicon oxynitride, silicon oxide, silicon carbonitride, silicon oxycarbonitride or a combination thereof.

The first front source/drain contact 170 and the second front source/drain contact 270 may be disposed inside the first interlayer insulating film 190. The front gate contact 175 may be disposed inside the gate capping pattern 145.

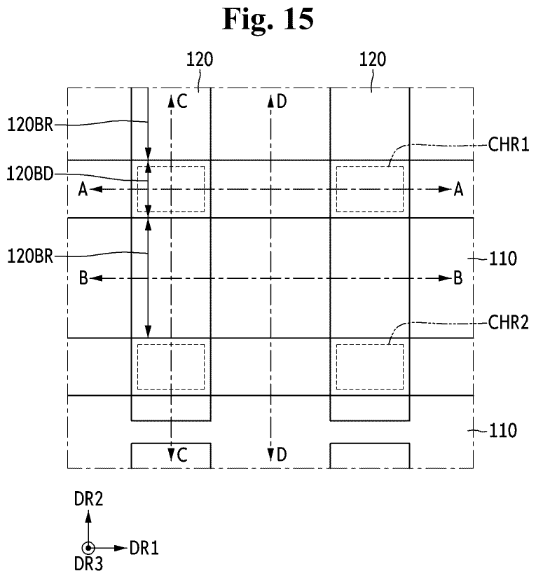

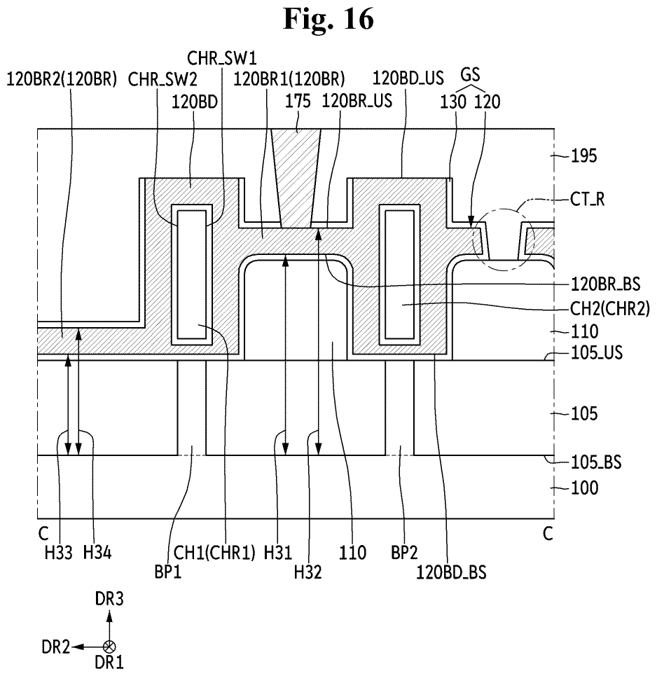

FIGS. 15 and 16 are diagrams for explaining a semiconductor device according to some embodiments. For convenience of explanation, with respect to embodiments illustrated in FIGS. 15 and 16, differences from those described using FIGS. 1 to 5 will be mainly described.

For reference, FIG. 15 is a layout diagram for explaining a semiconductor device according to some embodiments. FIG. 16 is a cross-sectional view taken along C-C of FIG. 15.

Referring to FIGS. 15 and 16, the semiconductor device according to some embodiments may not include the second protruding insulation pattern 210.

The second connecting gate electrode 120BR2 may extend along the first side 105_US of the field insulating film. For example, the second protruding insulation pattern (210 of FIG. 4) is not disposed between the second connecting gate electrode 120BR2 and the field insulating film 105. The gate insulating film 130 extending along the second side 120BR_BS of the connecting gate electrode in the second connecting gate electrode 120BR2 may be in contact with the first side 105_US of the field insulating film.

Because a thickness (t11 of FIG. 4) of the body gate electrode 120BD on the first side wall CHR_SW1 of the first channel region is equal to a thickness t12 of the body gate electrode 120BD on the second side wall CHR_SW2 of the first channel region, a boundary between the body gate electrode 120BD and the second connecting gate electrode 120BR2 may be determined/recognized, e.g., by the thickness t11 of the body gate electrode 120 DB.

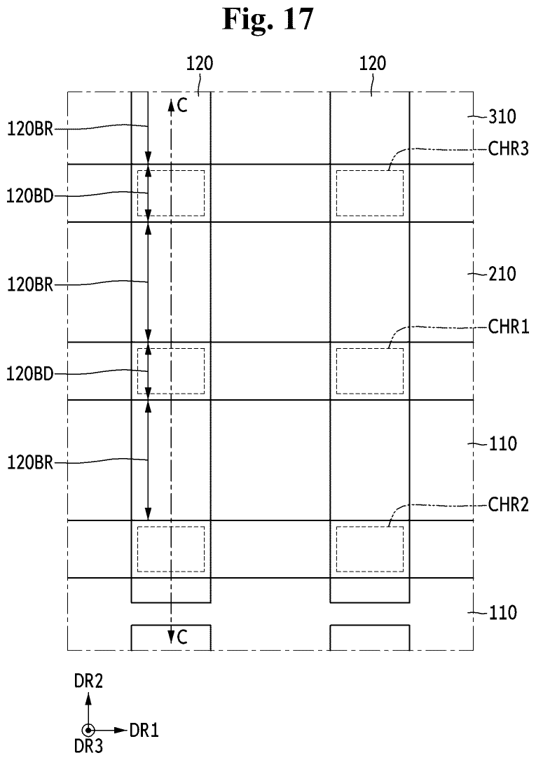

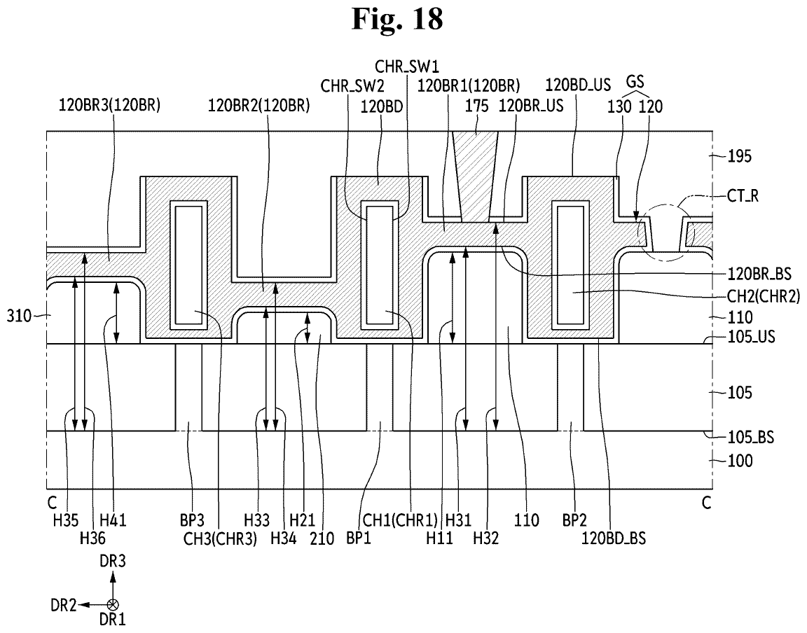

FIGS. 17 and 18 are diagrams for explaining a semiconductor device according to some embodiments. For convenience of explanation, with respect to embodiments illustrated in FIGS. 17 and 18, differences from those explained using FIGS. 1 to 5 will be mainly explained.

Referring to FIGS. 17 and 18, the semiconductor device according to some embodiments may further include a third channel region CHR3 and a third protruding insulation pattern 310.

A third lower pattern BP3 may protrude from the first substrate 100 in a third direction DR3. The third lower pattern BP3 may extend lengthwise in the first direction DR1. The third lower pattern BP3 may be spaced apart from the first lower pattern BP1 in the second direction DR2. The field insulating film 105 may be disposed on a side wall of the third lower pattern BP3.

Although no additional lower pattern is shown to be disposed between the first lower pattern BP1 and the third lower pattern BP3, the embodiment is not limited thereto. One or more lower patterns may be further disposed between the first lower pattern BP1 and the third lower pattern BP3.

The third channel region CHR3 may be disposed on the third lower pattern BP3. The third channel region CHR3 may overlap the third lower pattern BP3 in the third direction DR3. The third channel region CHR3 may include a third channel pattern CH3 spaced apart from the first side 105_US of the field insulating film in the third direction DR3.

As an example, the third channel region CHR3 may be disposed in a PMOS formation region. As another example, the third channel region CHR3 may be disposed in an NMOS formation region.

The third protruding insulation pattern 310 may be disposed on the field insulating film 105. The third protruding insulation pattern 310 may be disposed on the first side 105_US of the field insulating film. For example, the third protruding insulation pattern 310 may be in contact with the first side 105_US of the field insulating film.

The third protruding insulation pattern 310 may be spaced apart from the first protruding insulation pattern 110 and the second protruding insulation pattern 210 in the second direction DR2. For example, the second protruding insulation pattern 210 may be disposed between the first protruding insulation pattern 110 and the third protruding insulation pattern 310.

A height H41 of the third protruding insulation pattern 110 in the third direction DR3 may be different from the height H11 of the first protruding insulation pattern 110 in the third direction DR3. The height H41 of the third protruding insulation pattern 110 in the third direction DR3 may be different from the height H21 of the second protruding insulation pattern 210 in the third direction DR3.

For example, the height H41 of the third protruding insulation pattern 110 in the third direction DR3 may be smaller than the height H11 of the first protruding insulation pattern 110 in the third direction DR3. The height H41 of the third protruding insulation pattern 110 in the third direction DR3 may be greater than the height H21 of the second protruding insulation pattern 210 in the third direction DR3. Unlike the shown example, the height H41 of the third protruding insulation pattern 110 in the third direction DR3 may be smaller than the height H21 of the second protruding insulation pattern 210 in the third direction DR3.

The gate structure GS may be disposed on the first protruding insulation pattern 110, the second protruding insulation pattern 210, the third protruding insulation pattern 310, the first channel region CHR1, the second channel region CHR2, and the third channel region CHR3. For example, the gate structure GS may enclose the third channel region CHR3 in a cross-sectional view.

The gate electrode 120 may be disposed on the first protruding insulation pattern 110, the second protruding insulation pattern 210, and the third protruding insulation pattern 310.

The connecting gate electrode 120BR may include a first connecting gate electrode 120BR1, a second connecting gate electrode 120BR2, and a third connecting gate electrode 120BR3. The third connecting gate electrode 120BR3 may protrude/extend from the body gate electrode 120BD in the second direction DR2.

The third connecting gate electrode 120BR3 may be disposed on the third protruding insulation pattern 310. The third connecting gate electrode 120BR3 may overlap the third protruding insulation pattern 310 in the third direction DR3. The third protruding insulation pattern 310 may be disposed between the third connecting gate electrode 120BR3 and the field insulating film 105.

A height H31 from the second side 105_BS of the field insulating film to the second side 120BR_BS of the connecting gate electrode at the first connecting gate electrode 120BR1 may be different from a height H35 from the second side 105_BS of the field insulating film to the second side 120BR_BS of the connecting gate electrode at the third connecting gate electrode 120BR3. The height H33 from the second side 105_BS of the field insulating film to the second side 120BR_BS of the connecting gate electrode at the second connecting gate electrode 120BR2 may be different from the height H35 from the second side 105_BS of the field insulating film to the second side 120BR_BS of the connecting gate electrode at the third connecting gate electrode 120BR3.

The height H32 from the second side 105_BS of the field insulating film to the first side 120BR_US of the connecting gate electrode at the first connecting gate electrode 120BR1 may be different from a height H36 from the second side 105_BS of the field insulating film to the first side 120BR_US of the connecting gate electrode at the third connecting gate electrode 120BR3. The height H34 from the second side 105_BS of the field insulating film to the first side 120BR_US of the connecting gate electrode at the second connecting gate electrode 120BR2 may be different from the height H36 from the second side 105_BS of the field insulating film to the first side 120BR_US of the connecting gate electrode at the third connecting gate electrode 120BR3.

A heights (H36-H35) of the third connecting gate electrode 120BR3 in the third direction DR3 may be equal to a heights (H32-H31) of the first connecting gate electrode 120BR1 in the third direction DR3. The height (H36-H35) of the third connecting gate electrode 120BR3 in the third direction DR3 may be equal to the height (H34-H33) of the second connecting gate electrode 120BR2 in the third direction DR3.

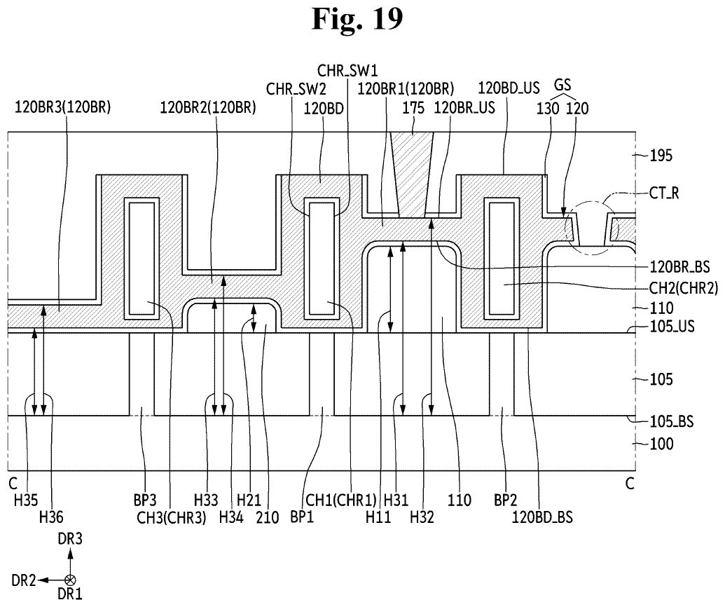

FIG. 19 is a diagram for explaining a semiconductor device according to some embodiments. For convenience of explanation, with respect to embodiments illustrated in FIG. 19, differences from those explained using FIGS. 17 and 18 will be mainly explained.

Referring to FIG. 19, the semiconductor device according to some embodiments may not include the third protruding insulation pattern 310.

The third connecting gate electrode 120BR3 may extend along the first side 105_US of the field insulating film. The third protruding insulation pattern (310 of FIG. 18) is not disposed between the third connecting gate electrode 120BR3 and the field insulating film 105. The gate insulating film 130 extending along the second side 120BR_BS of the connecting gate electrode in the third connecting gate electrode 120BR3 may be in contact with the first side 105_US of the field insulating film.

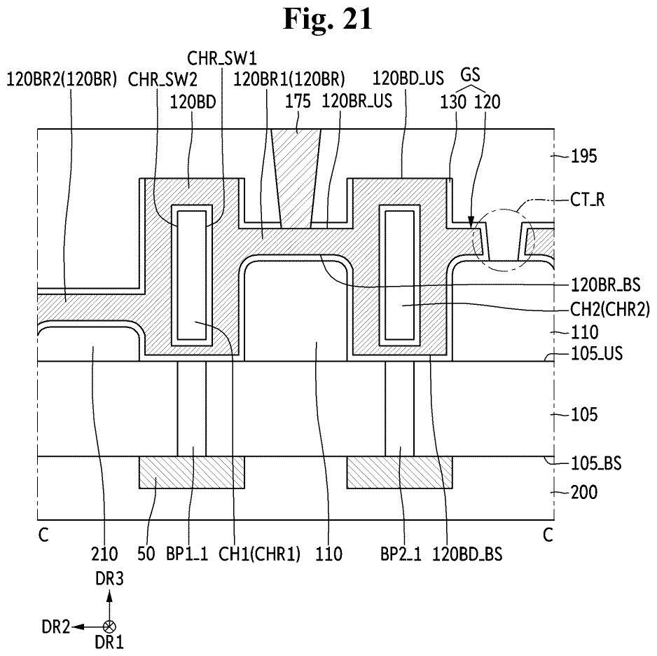

FIGS. 20 to 22 are diagrams for explaining a semiconductor device according to some embodiments. For convenience of explanation, with respect to embodiments illustrated in FIGS. 20 to 22, differences from those explained using FIGS. 1 to 5 will be mainly explained.

Referring to FIGS. 20 to 22, the semiconductor device according to some embodiments may further include a back source/drain contact 171 and a back wiring line 50.

A first lower pattern BP1_1 and a second lower pattern BP2_1 may be disposed on a second substrate 200. The second substrate 200 includes an insulating material, and may include at least one of silicon oxide, silicon nitride, and a combination thereof. The second substrate 200 may be a substrate formed by a deposition process or the like after the first substrate 100 of FIGS. 2 to 5 is removed during a fabricating process of the semiconductor device.

As an example, each of the first lower pattern BP1_1 and the second lower pattern BP2_1 may include a semiconductor material.

As another example, each of the first lower pattern BP1_1 and the second lower pattern BP2_1 may include an insulating material. The first lower pattern BP1_1 and the second lower pattern BP2_1 may include at least one of silicon oxide, silicon nitride or silicon oxynitride. When the first lower pattern BP1_1 and the second lower pattern BP2_1 include the same insulating material as the field insulating film 105, the boundary between the field insulating film 105 and the first and second lower patterns BP1_1 and BP2_1 may not be divided. In this example, the field insulating film 105 and the first and second lower patterns BP1_1 and BP2_1 may be integrally formed as one body, e.g., without detectable boundaries between the field insulating film 105 and the first and second lower patterns BP1_1 and BP2_1.

The field insulating film 105 may be in contact with the second substrate 200. The second side 105_BS of the field insulating film faces the second substrate 200.

The back wiring line 50 may be disposed inside the second substrate 200. Although the back wiring line 50 is shown to extend in the first direction DR1, this is only for convenience of explanation, and the embodiment is not limited thereto. Unlike the shown example, the back wiring line 50 may include a line portion and a via portion. The via portion of the back wiring line 50 may protrude from the line portion of the back wiring line 50 in the third direction DR3.

As an example, the back wiring line 50 may be a power line that supplies power to the semiconductor device. As another example, the back wiring line 50 may be a signal line that supplies an operating signal of the semiconductor device.

The back source/drain contact 171 may be disposed between the first source/drain pattern 150 and the back wiring line 50. The back source/drain contact 171 may electrically connect the first source/drain pattern 150 and the back wiring line 50. For example, a part of the first source/drain pattern 150 may be electrically connected to and/or contact the back source/drain contact 171.

A back contact silicide film 156 may be disposed between the back source/drain contact 171 and the first source/drain pattern 150.

Although each of the back source/drain contact 171 and the back wiring line 50 is shown as being a single conductive film, the embodiment is not limited thereto. Unlike the shown example, at least one of the back source/drain contact 171 and the back wiring line 50 may have a multiple conductive film structure including a barrier film and a filling film. Each of the back source/drain contact 171 and the back wiring line 50 may include at least one of, for example, a metal, a conductive metal nitride, a conductive metal carbide, a conductive metal oxide, a conductive metal carbonitride or a two-dimensional material.

Although not shown, when the first lower pattern BP1_1 includes a semiconductor material, a back contact liner may be disposed between the back source/drain contact 171 and the first lower pattern BP1_1. The back contact liner includes an insulating material.

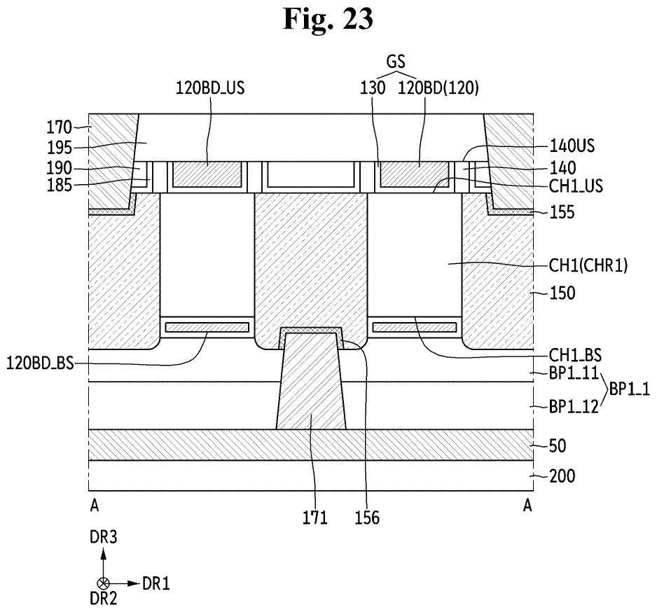

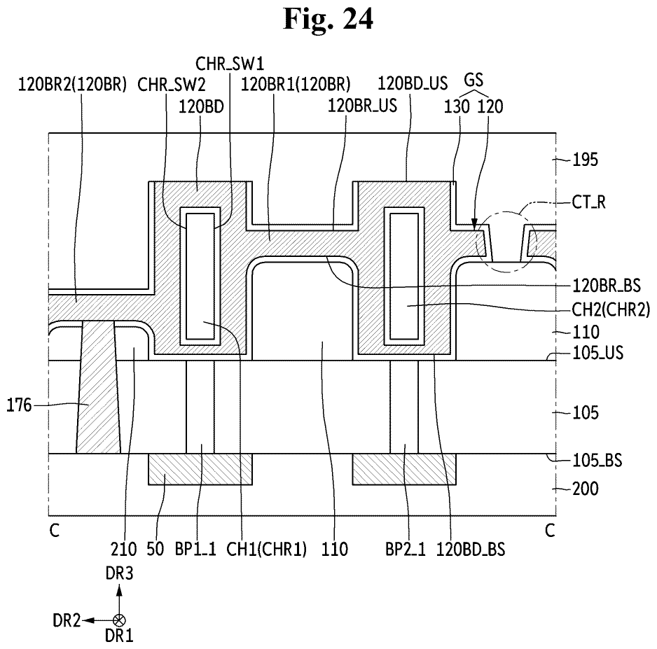

FIGS. 23 and 24 are diagrams for explaining a semiconductor device according to some embodiments. For convenience of explanation, with respect to embodiments illustrated in FIGS. 23 and 24, differences from those described using FIGS. 20 to 22 will be mainly explained.

Referring to FIG. 23, in the semiconductor device according to some embodiments, the first lower pattern BP1_1 may include a first sub lower pattern BP1_11 and a second sub lower pattern BP1_12.

The second sub lower pattern BP1_12 may be disposed between the first sub lower pattern BP1_11 and the back wiring line 50. The first sub lower pattern BP1_11 may include a semiconductor material. The second sub lower pattern BP1_12 may include an insulating material.

Referring to FIG. 24, the semiconductor device according to some embodiments may include a back gate contact 176.

The back gate contact 176 may be disposed inside the field insulating film 105. The back gate contact 176 penetrates the field insulating film 105, and may be electrically connected to and/or contact the gate electrode 120. For example, the back gate contact 176 may pass through the field insulating film 105 in the third direction DR3, and the back gate contact 176 may pass through the second protruding insulation pattern 210 in the third direction DR3.

For example, the back gate contact 176 may be electrically connected to and/or contact the connecting gate electrode 120BR. Unlike the shown example, the back gate contact 176 may be electrically connected to and/or contact the body gate electrode 120BD.

Although the back gate contact 176 is shown to have a single conductive film/layer structure, the embodiment is not limited thereto. The back gate contact 176 may include at least one of, for example, a metal, a conductive metal nitride, a conductive metal carbide, a conductive metal oxide, a conductive metal carbonitride or a two-dimensional material (2D material).

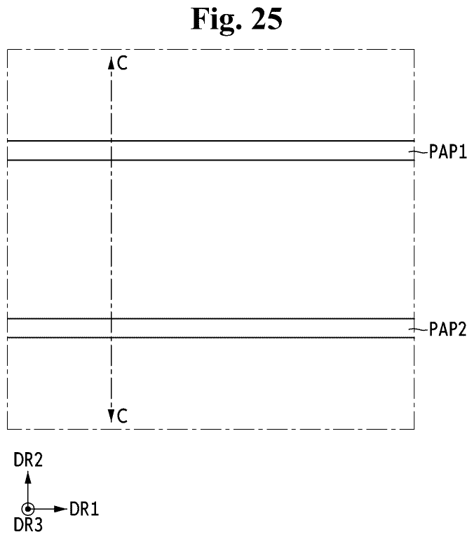

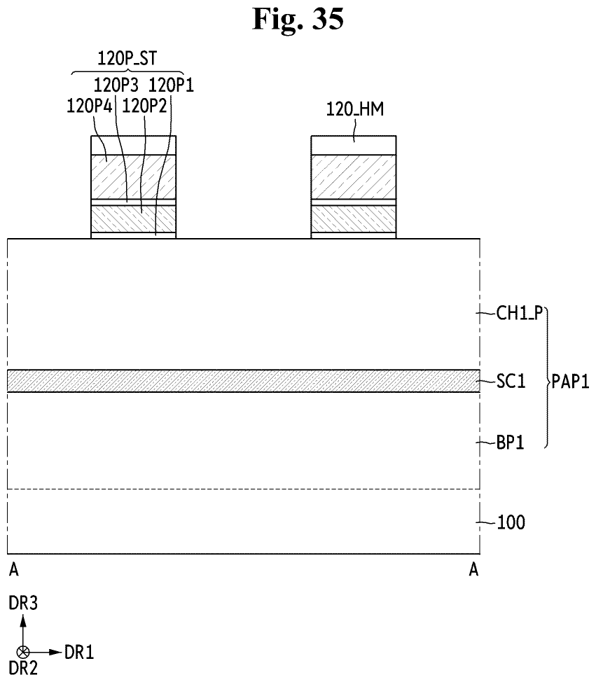

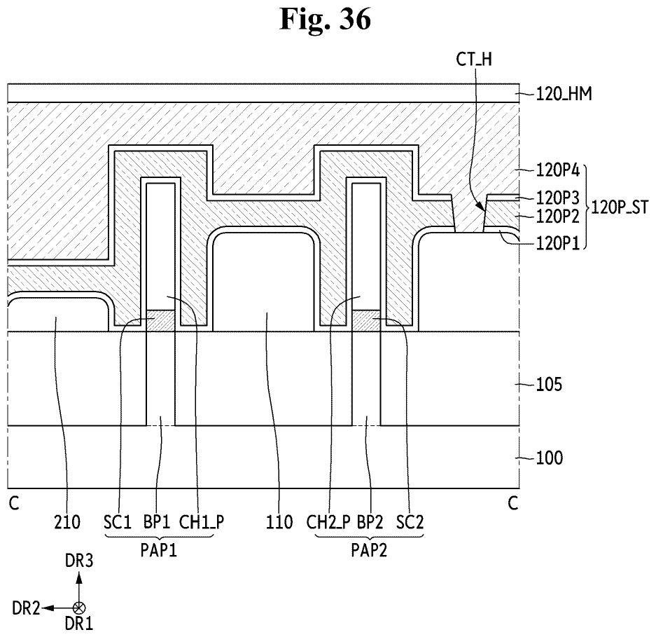

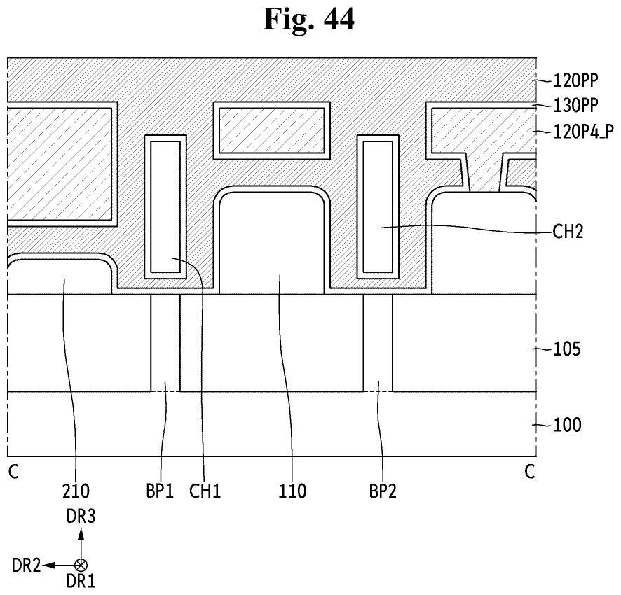

FIGS. 25 to 46 are intermediate stage diagrams for explaining a method for fabricating a semiconductor device according to some embodiments.

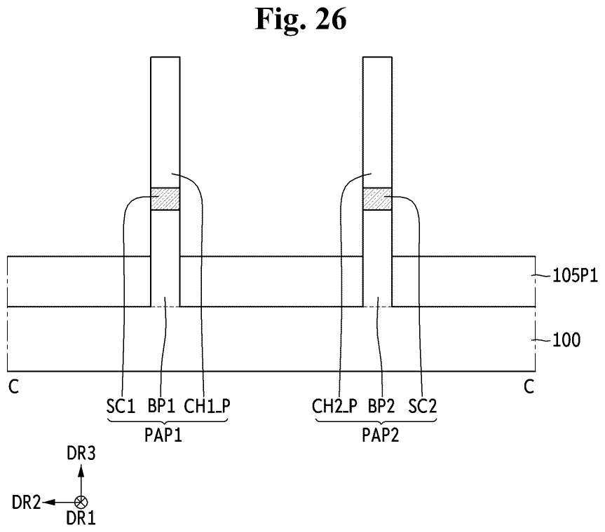

Referring to FIGS. 25 and 26, a first pre-fin-shaped pattern PAP1 and a second pre-fin-shaped pattern PAP2 may be formed on the first substrate 100.

Each of the first pre-fin-shaped pattern PAP1 and the second pre-fin-shaped pattern PAP2 may protrude from the first substrate 100 in the third direction DR3. Each of the first pre-fin-shaped pattern PAP1 and the second pre-fin-shaped pattern PAP2 may extend lengthwise in the first direction DR1. The first pre-fin-shaped pattern PAP1 and the second pre-fin-shaped pattern PAP2 may be spaced apart from each other in the second direction DR2.

The first pre-fin-shaped pattern PAP1 may include a first lower pattern BP1, a first sacrificial pattern SC1, and a first pre-channel pattern CH1_P. The second pre-fin-shaped pattern PAP2 may include a second lower pattern BP2, a second sacrificial pattern SC2, and a second pre-channel pattern CH2_P. For example, each of the first pre-channel pattern CH1_P and the second pre-channel pattern CH2_P may include or may be a crystalline silicon film. In another example, each of the first sacrificial pattern SC1 and the second sacrificial pattern SC2 may include or may be a crystalline silicon-germanium film.

Next, a first pre-field insulating film 105P1 may be formed on the first substrate 100. The first pre-field insulating film 105P1 may cover a part of a side wall of the first lower pattern BP1 and a part of a side wall of the second lower pattern BP2.

Unlike the shown example, as an example, the first pre-fin-shaped pattern PAP1 and the second pre-fin-shaped pattern PAP2 may be the first fin-shaped pattern CHF1 and the second fin-shaped pattern CHF2 described with respect to and shown in FIGS. 8 and 9. As another example, the first pre-fin-shaped pattern PAP1 may include a plurality of first sacrificial patterns SC1 and a plurality of first pre-channel patterns CH1_P that are stacked alternately. The second pre-fin-shaped pattern PAP2 may include a plurality of second sacrificial patterns SC2 and a plurality of second pre-channel patterns CH2_P that are stacked alternately.

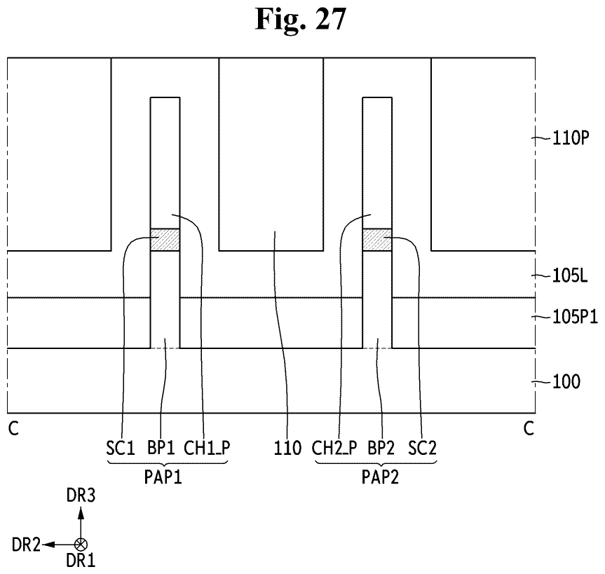

Referring to FIG. 27, a field liner film 105L may be formed on the first pre-field insulating film 105P1.

The field liner film 105L may be formed along an upper side of the first pre-field insulating film 105P1. The upper side of the first pre-field insulating film 105P1 may be an upper surface or a top surface of the first pre-field insulating film 105P1. The field liner film 105L may be formed along the profiles of the first pre-fin-shaped pattern PAP1 and the second pre-fin-shaped pattern PAP2 that protrude upward beyond/from the upper side of the first pre-field insulating film 105P1.

The field liner film 105L may be formed, for example, but is not limited to, using an atomic layer deposition (ALD) method. The field insulating liner film 105L may include, for example, but is not limited to, silicon oxide.

A protruding insulation film 110P may be formed on the field liner film 105L. More specifically, a pre-protruding insulation film may be formed on the field liner film 105L. The pre-protruding insulation film may entirely cover the field liner film 105L. Next, a part of the pre-protruding insulation film may be removed to expose the field liner film 105L formed on the upper side/surface of the first pre-fin-shaped pattern PAP1 and the upper side/surface of the second pre-fin-shaped pattern PAP2. Thus, the protruding insulation film 110P may be formed.

The protruding insulation film 110P may include a material having an etching selectivity with respect to the field liner film 105L. For example, the protruding insulation film 110P may include at least one of silicon nitride or silicon oxynitride.

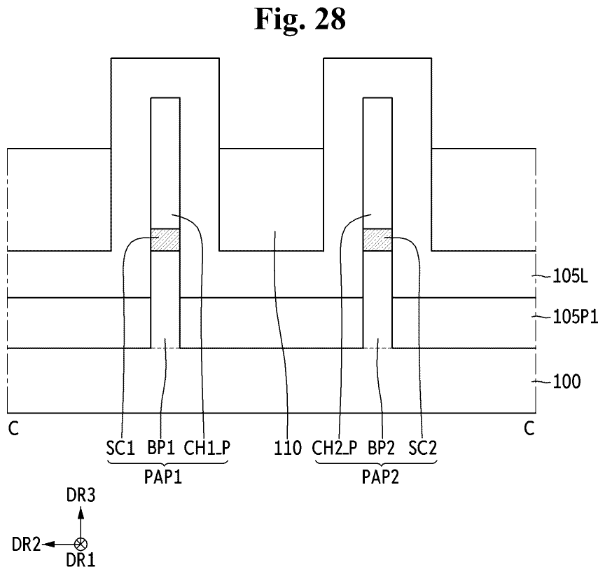

Referring to FIGS. 27 and 28, a first protruding insulation pattern 110 may be formed by removing a part of the protruding insulation film 110P.

The first protruding insulation pattern 110 may be formed on the field liner film 105L. A part of the protruding insulation film 110P may be removed, using an etching selectivity between the protruding insulation film 110P and the field liner film 105L.

The first protruding insulation pattern 110 may extend, for example, lengthwise in the first direction DR1. A plurality of first protruding insulation patterns 110 may be spaced apart from each other in the second direction DR2.

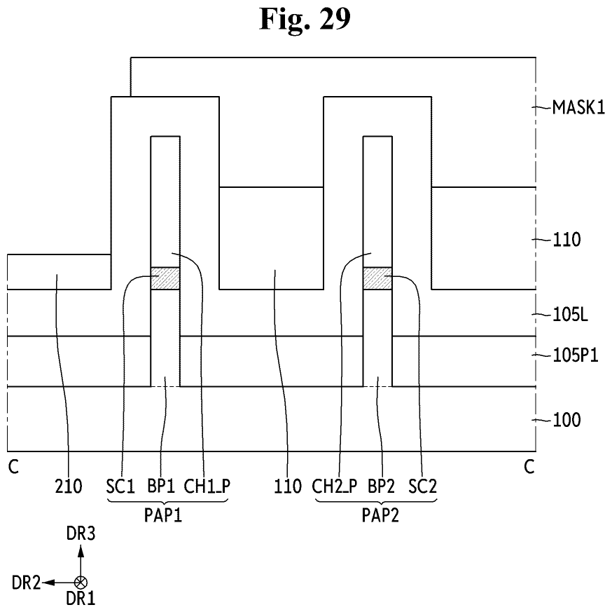

Referring to FIGS. 28 and 29, a first mask pattern MASK1 may be formed on the first protruding insulation pattern 110 and the field liner film 105L.

The first mask pattern MASK1 may expose at least one of the plurality of first protruding insulation patterns 110.

Next, a part of the exposed first protruding insulation pattern 110 may be removed, using the first mask pattern MASK1 as an etching mask. Thus, the second protruding insulation pattern 210 may be formed on the field liner film 105L.

Unlike the shown example, the exposed first protruding insulation pattern 110 may be removed, by using the first mask pattern MASK1 as an etching mask.

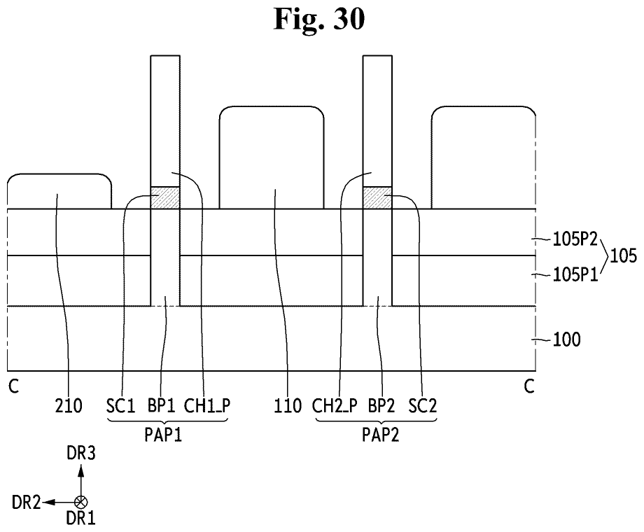

Referring to FIGS. 29 and 30, the first mask pattern MASK1 may be removed.

After removing the first mask pattern MASK1, a part of the field liner film 105L may be removed. The remainder of the field liner film 105L may be a second pre-field insulating film 105P2.

The field insulating film 105 including the first pre-field insulating film 1 05P1 and the second pre-field insulating film 105P2 may be formed on the first substrate 100.

The field insulating film 105 may cover a part of the side wall of the first pre-fin-shaped pattern PAP1 and a part of the side wall of the second pre-fin-shaped pattern PAP2. The field insulating film 105 may cover a side wall of the first lower pattern BP1 and a side wall of the second lower pattern BP2. The first protruding insulation pattern 110 and the second protruding insulation pattern 210 may be formed on an upper side of the field insulating film 105. The upper side of the field insulating film 105 may be an upper surface or a top surface of the field insulating film 105. The first protruding insulation pattern 110 may be spaced apart from the first pre-fin-shaped pattern PAP1 and the second pre-fin-shaped pattern PAP2 in the second direction DR2.

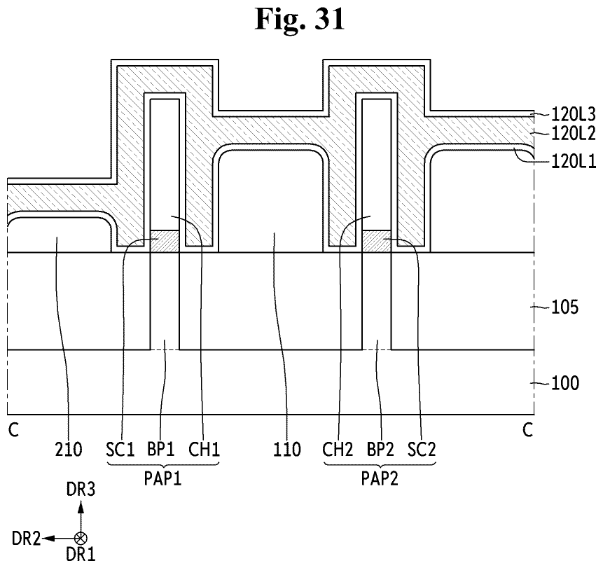

Referring to FIG. 31, a lower dummy gate liner film 120L1 may be formed on the first protruding insulation pattern 110, the second protruding insulation pattern 210, the first pre-fin-shaped pattern PAP1, and the second pre-fin-shaped pattern PAP2.

The lower dummy gate liner film 120L1 may be formed along the profiles of the first pre-fin-shaped pattern PAP1 and the second pre-fin-shaped pattern PAP2 that protrude upward beyond/from the upper side of the field insulating film 105. The lower dummy gate liner film 120L1 may be formed along the profile of the first protruding insulation pattern 110 and the profile of the second protruding insulation pattern 210. The lower dummy gate liner film 120L1 may include, for example, but is not limited to, silicon oxide.

Next, a dummy gate film 120L2 may be formed on the dummy gate liner film 120L1. The dummy gate film 120L2 may be formed at a uniform thickness along the lower dummy gate liner film 120L1. The dummy gate film 120L2 may include, for example, but is not limited to, silicon-germanium.

An upper dummy gate liner film 120L3 may be formed on the dummy gate film 120L2. The upper dummy gate liner film 120L3 may be formed along the profile of the dummy gate film 120L2. The upper dummy gate liner film 120L3 may include, for example, but is not limited to, silicon oxide.

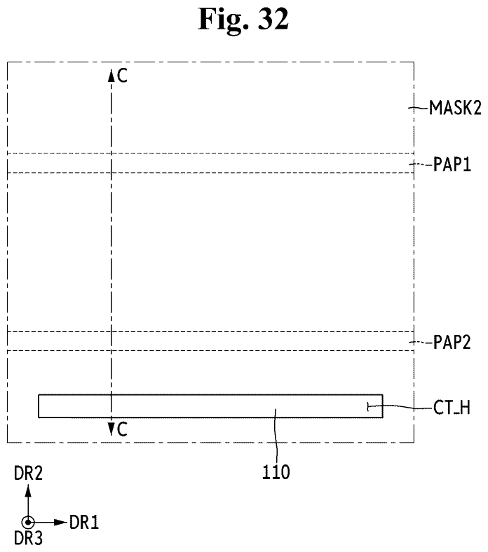

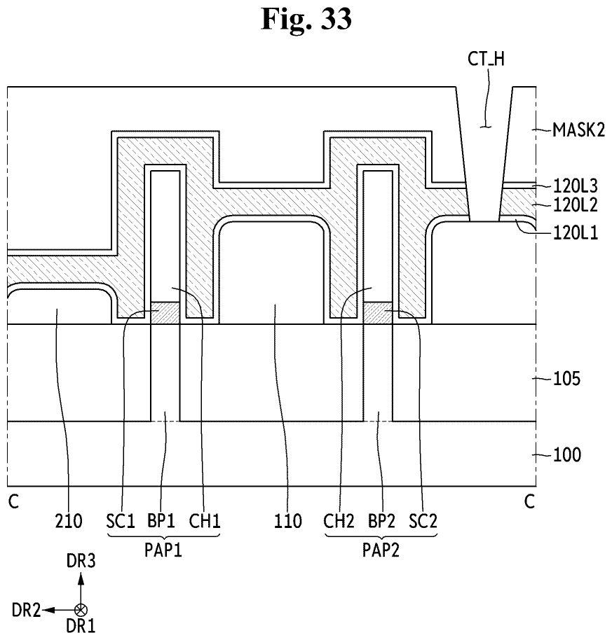

Referring to FIGS. 32 and 33, a second mask pattern MASK2 may be formed on the upper dummy gate liner film 120L3.

A gate separation hole CT_H may be formed inside the lower dummy gate liner film 120L1, the dummy gate film 120L2, and the upper dummy gate liner film 120L3, by using the second mask pattern MASK2 as a mask. Although the gate separation hole CT_H is shown as a line shape extending lengthwise in the first direction DR1, this is only for convenience of explanation, and the embodiment is not limited thereto.

Referring to FIGS. 32 to 36, after removing the second mask pattern MASK2, a dummy gate capping film may be formed on the upper dummy gate liner film 120L3.

The dummy gate capping film may fill the gate separation hole CT_H. The dummy gate capping film may include, but is not limited to, silicon.

Next, the lower dummy gate liner film 120L1, the dummy gate film 120L2, the upper dummy gate liner film 120L3, and the dummy gate capping film may be patterned to form a dummy gate pattern 120P_ST. The dummy gate pattern 120P_ST may include a lower dummy gate liner 120P1, a dummy gate electrode 120P2, an upper dummy gate liner 120P3, and a dummy gate capping pattern 120P4. The lower dummy gate liner film 120L1 may be patterned to form the lower dummy gate liner 120P1. The dummy gate film 120L2 may be patterned to form the dummy gate electrode 120P2. The upper dummy gate liner film 120L3 may be patterned to form the upper dummy gate liner 120P3. The dummy gate capping film may be patterned to form the dummy gate capping pattern 120P4. The dummy gate capping pattern 120P4 may fill the gate separation hole CT_H.

The dummy gate pattern 120P_ST may be formed on the first pre-fin-shaped pattern PAP1, the second pre-fin-shaped pattern PAP2, the first protruding insulation pattern 110, and the second protruding insulation pattern 210. The dummy gate pattern 120P_ST may intersect the first pre-fin-shaped pattern PAP1 and the second pre-fin-shaped pattern PAP2. The dummy gate pattern 120P_ST may extend lengthwise in the second direction DR2.

For example, a gate hard mask pattern 120_HM may be formed on the dummy gate capping film. The gate hard mask pattern 120_HM may extend lengthwise in the second direction DR2 along the dummy gate capping film. The lower dummy gate liner film 120L1, the dummy gate film 120L2, the upper dummy gate liner film 120L3, and the dummy gate capping film may be patterned, by using the gate hard mask pattern 120_HM as an etching mask to form the dummy gate pattern 120P_ST. The gate hard mask pattern 120_HM may include, but is not limited to, silicon nitride.

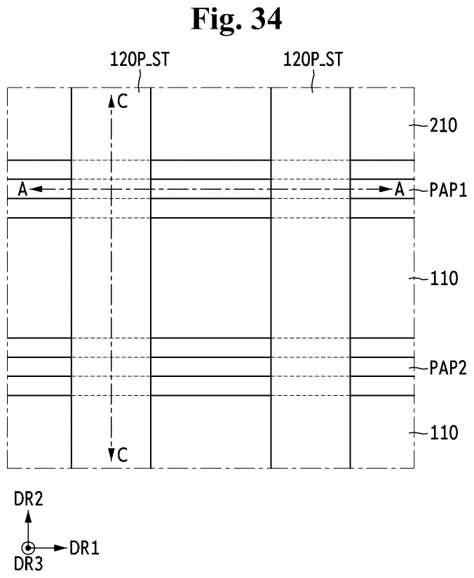

Referring to FIGS. 34 to 37, the gate spacer 140 may be formed on the side wall of the dummy gate pattern 120P_ST.

While the gate spacer 140 is formed, a source/drain recess 150R may be formed in the first pre-channel pattern CH1_P and the first sacrificial pattern SC1, by using the gate spacer 140 and the dummy gate pattern 120P_ST as a mask. The source/drain recess 150R may separate the first pre-channel pattern CH1_P into a plurality of first channel patterns CH1. The source/drain recess 150R may separate the first sacrificial pattern SC1 into a plurality of first sacrificial dummy patterns SC1_P. In a cross-sectional view, the bottom side of the source/drain recess 150R may be defined by the first lower pattern BP1, and the side wall of the source/drain recess 150R may be defined by the first channel pattern CH1 and the first sacrificial dummy pattern SC1_P. The bottom side of the source/drain recess 150R may be a bottom surface of the source/drain recess 150R. The first pre-fin-shaped pattern PAP1 may include a first lower pattern BP1, a plurality of first channel patterns CH1, and a plurality of first sacrificial dummy patterns SC1_P.

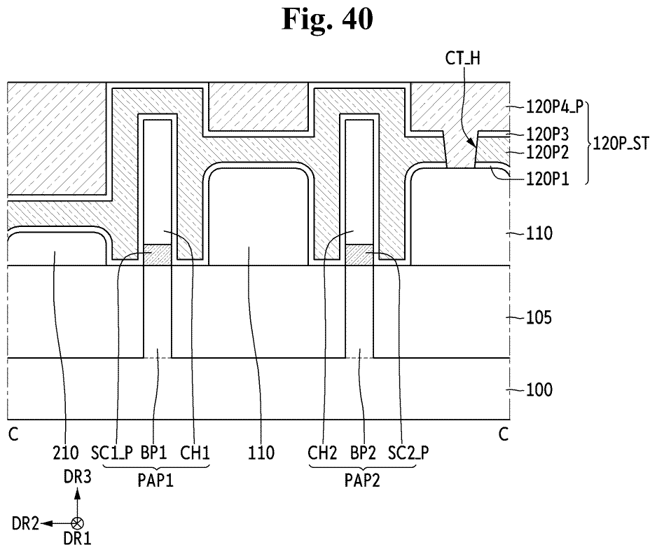

Although not shown, the second pre-channel pattern (CH2_P of FIG. 26) may be separated into a plurality of second channel patterns (CH2 of FIG. 40), e.g., by source/drain recesses 150R. The second sacrificial pattern (SC2 of FIG. 26) may be separated into a plurality of second sacrificial dummy patterns (SC2_P of FIG. 40). The second pre-fin-shaped pattern PAP2 may include a second lower pattern BP2, a plurality of second channel patterns CH2, and a plurality of second sacrificial dummy patterns SC2_P.

Unlike the aforementioned example, before the gate spacer 140 is formed, by removing the first sacrificial pattern SC1 and the second sacrificial pattern SC2 that do not overlap the dummy gate pattern 120P_ST in the third direction DR3, a sacrificial pattern cavity may be formed. Next, while the gate spacer 140 is formed, the sacrificial pattern cavity may be filled with an insulating material. A part of the first sacrificial pattern SC1 including a semiconductor material and a part of the second sacrificial pattern SC2 including a semiconductor material may be substituted with an insulating material. For example, each of the first sacrificial pattern SC1 and the second sacrificial pattern SC2 may include a semiconductor material portion and an insulating material portion that are disposed alternately in the first direction DR1. In this case, the source/drain recess 150R may be formed inside the first pre-channel pattern CH1_P. The source/drain recess 150R may not separate the first sacrificial pattern SC1. In a cross-sectional view, the bottom side of the source/drain recess 150R may be defined by a first sacrificial pattern SC1 portion formed of an insulating material, and the side wall of the source/drain recess 150R may be defined by the first channel pattern CH1. The first pre-fin-shaped pattern PAP1 may include a first lower pattern BP1, a plurality of first channel patterns CH1, and a first sacrificial pattern SC1 including a semiconductor material portion and an insulating material portion disposed alternately in the first direction DR1.

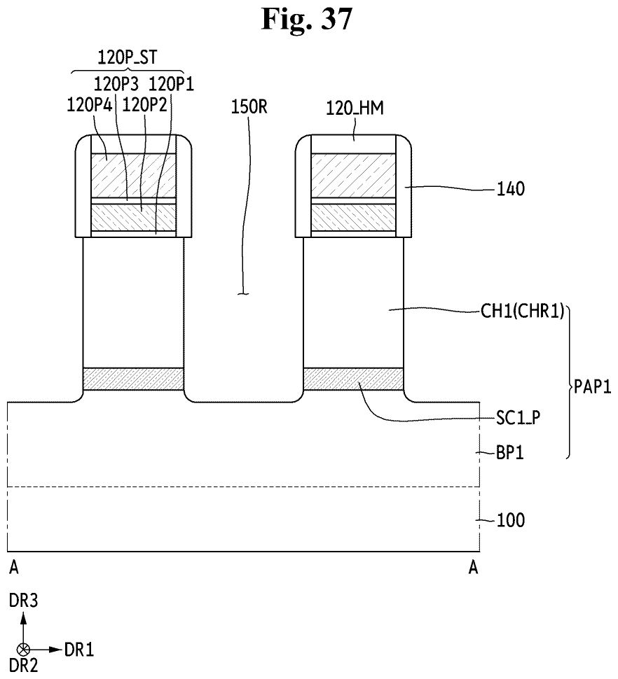

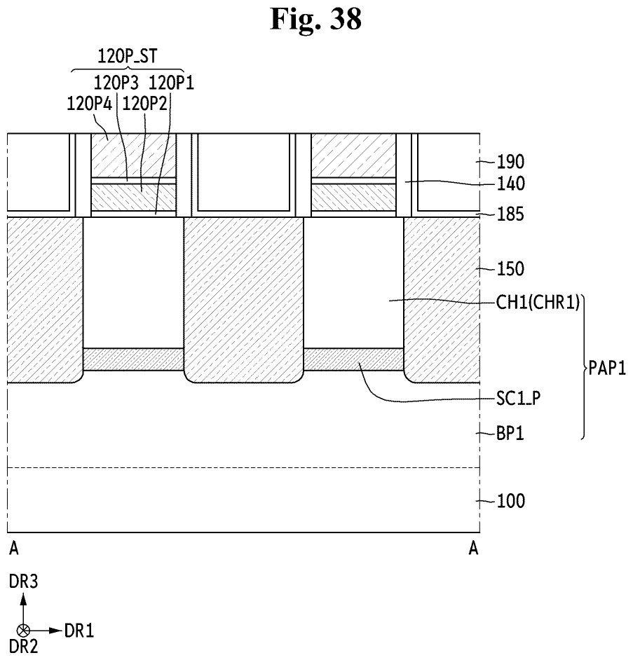

Referring to FIGS. 37 and 38, the first source/drain pattern 150 may be formed on the first lower pattern BP1.

The first source/drain pattern 150 may fill the source/drain recess 150R. The first source/drain pattern 150 is electrically connected to and/or contact the first channel pattern CH1.

Unlike the shown example, each of the first sacrificial pattern SC1 and the second sacrificial pattern SC2 may include a semiconductor material portion and an insulating material portion that are disposed alternately in the first direction DR1. In this case, in the cross-sectional view such as FIG. 2, the first sacrificial pattern SC1 corresponding to the insulating material portion may remain between the first channel pattern CH1 and the first lower pattern BP1. Also, in a cross-sectional view such as FIG. 5, the first sacrificial pattern SC1 corresponding to the insulating material portion may be disposed between the first source/drain pattern 150 and the first lower pattern BP1, and the second sacrificial pattern SC2 corresponding to the insulating material portion may be disposed between the second source/drain pattern 250 and the second lower pattern BP2.

The source/drain etching stop film 185 and the first interlayer insulating film 190 may be formed on the first source/drain pattern 150.

Next, the upper side/surface of the dummy gate pattern 120P_ST may be exposed by removing a part of the first interlayer insulating film 190, a part of the source/drain etching stop film 185, and the gate hard mask pattern 120_HM. The gate hard mask pattern 120_HM may be removed to expose the dummy gate capping pattern 120P4. A part of the gate spacer 140 may be removed while the gate hard mask pattern 120_HM is removed, and the dummy gate capping pattern 120P4 is exposed.

Referring to FIGS. 38 to 40, a part of the dummy gate capping pattern 120P4 may be removed to form a pre-gate capping pattern 120P4_P.

The pre-gate capping pattern 120P4_P may expose the upper dummy gate liner 120P3. The dummy gate pattern 120P_ST may include a lower dummy gate liner 120P1, a dummy gate electrode 120P2, an upper dummy gate liner 120P3, and a pre-gate capping pattern 120P4_P.

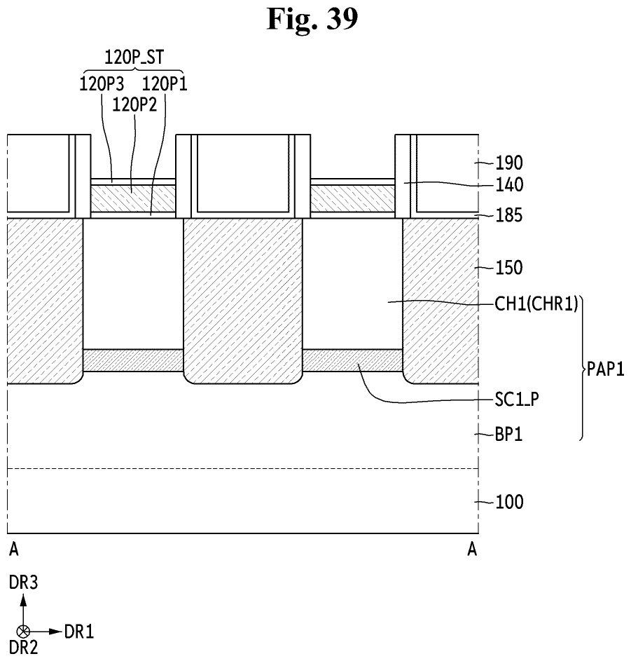

Referring to FIGS. 39 to 42, a gate electrode cavity 120_CAV may be formed by removing the lower dummy gate liner 120P1, the dummy gate electrode 120P2, and the upper dummy gate liner 120P3.

The gate electrode cavity 120_CAV may be defined between the gate spacers 140 adjacent to each other in the first direction DR1. The gate electrode cavity 120_CAV may be formed between the pre-gate capping pattern 120P4_P and the first protruding insulation pattern 110, and between the pre-gate capping pattern 120P4_P and the second protruding insulation pattern 210. The gate electrode cavity 120_CAV may be formed between the first pre-fin-shaped pattern PAP1 and the first protruding insulation pattern 110, and between the first pre-fin-shaped pattern PAP1 and the second protruding insulation pattern 210. The gate electrode cavity 120_CAV may be formed between the second pre-fin-shaped pattern PAP2 and the first protruding insulation pattern 110.

While removing the lower dummy gate liner 120P1, the dummy gate electrode 120P2, and the upper dummy gate liner 120P3, the first sacrificial dummy pattern SC1_P and the second sacrificial dummy pattern SC2_P may be removed. The first channel pattern CH1 may be spatially separated from the first lower pattern BP1, e.g., in a cross-sectional view. The second channel pattern CH2 may be spatially separated from the second lower pattern BP2, e.g., in the cross-sectional view.

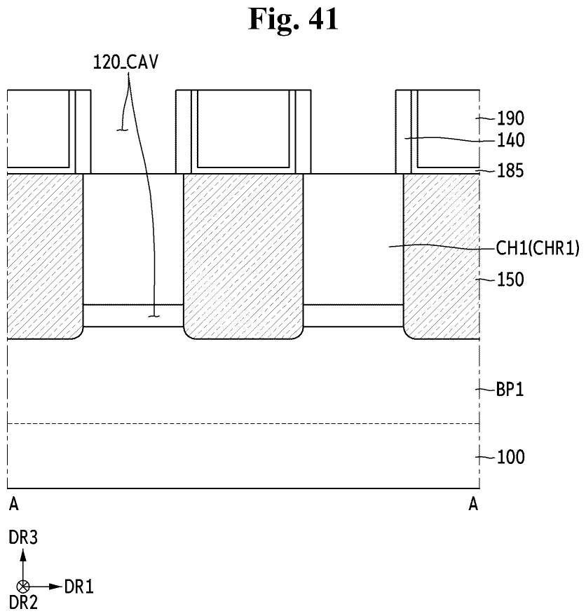

Referring to FIGS. 41 to 44, the pre-gate insulating film 130PP and the pre-gate electrode 120PP may be formed inside the gate electrode cavity 120_CAV.

The pre-gate insulating film 130PP and the pre-gate electrode 120PP may be formed, for example, but are not limited to, by an atomic layer deposition (ALD).

The pre-gate insulating film 130PP may be formed along the upper side of the pre-gate capping pattern 120P4_P. The pre-gate electrode 120PP may be formed on the upper side of the pre-gate capping pattern 120P4_P. The upper side of the pre-gate capping pattern 120P4_P may be an upper surface or a top surface of the pre-gate capping pattern 120P4_P.

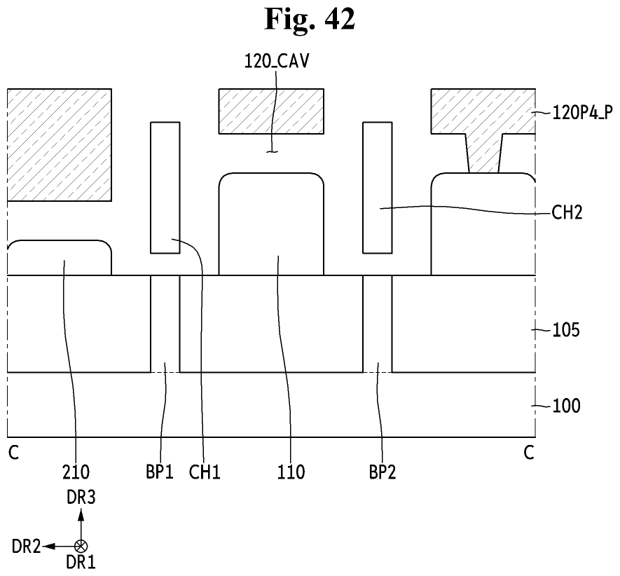

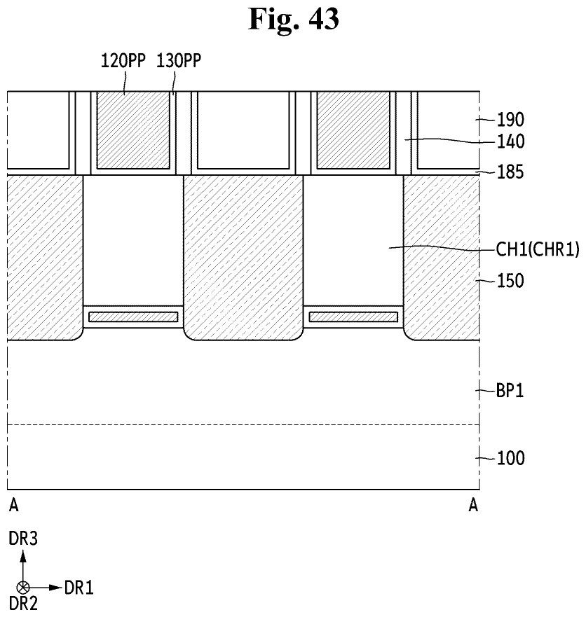

Referring to FIGS. 43 to 45, the gate structure GS including the gate electrode 120 and the gate insulating film 130 may be formed in the gate electrode cavity (120_CAV of FIG. 42), by removing a part of the pre-gate insulating film 130PP and a part of the pre-gate electrode 120PP.

The pre-gate insulating film 130PP formed along the upper side of the pre-gate capping pattern 120P4_P may be removed. The pre-gate electrode 120PP formed on the upper side of the pre-gate capping pattern 120P4_P may be removed.

Although not shown, a part of the pre-gate insulating film 130PP and a part of the pre-gate electrode 120PP may be removed, using a planarization process. While the planarization process is performed, a part of the gate spacer 140 and a part of the first interlayer insulating film 190 may also be removed. Accordingly, the upper side/surface of the gate electrode 120 may be disposed in the same plane as the upper side/surface of the gate spacer 140 and the upper side/surface of the first interlayer insulating film 190.

Unlike the aforementioned example, a part of the pre-gate insulating film 130PP and a part of the pre-gate electrode 120PP may be removed, using an etch-back process. In such a case, a part of the gate spacer 140 and a part of the first interlayer insulating film 190 may protrude beyond/from the gate electrode 120 in the third direction DR3.

In the following description, a case where a part of the gate spacer 140 and a part of the first interlayer insulating film 190 are also removed when forming the gate electrode 120 and the gate insulating film 130 is used.

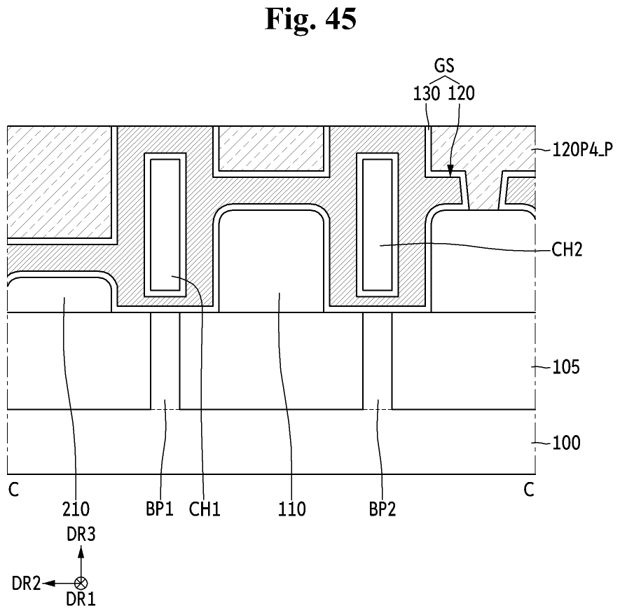

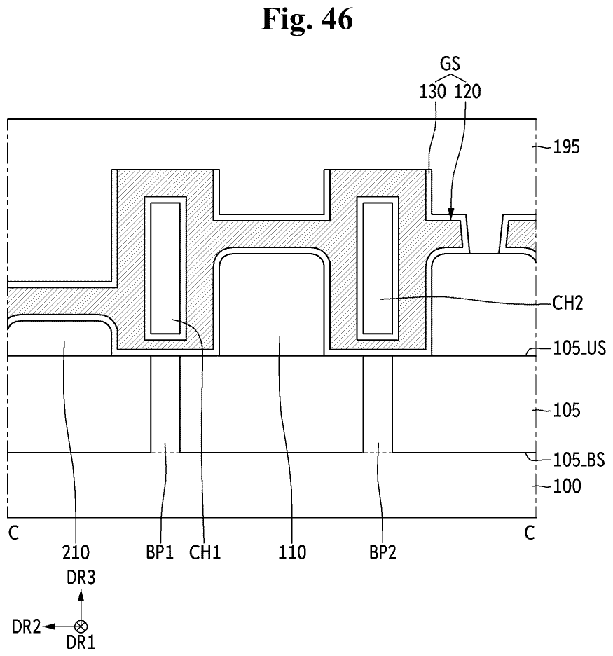

Referring to FIGS. 45 and 46, the pre-gate capping pattern 120P4_P may be replaced with a second interlayer insulating film 195.

After removing the pre-gate capping pattern 120P4_P, the second interlayer insulating film 195 may fill the space from which the pre-gate capping pattern 120P4_P has been removed.

Although embodiments of the present disclosure have been described above with reference to the accompanying drawings, the present disclosure may not be limited to embodiments and may be implemented in various different forms. For example, even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

Those of ordinary skill in the technical field to which the present disclosure belongs will be able to appreciate that the present disclosure may be implemented in other specific forms without changing the technical idea or essential features of the present disclosure. Therefore, it should be understood that embodiments as described above are not restrictive but illustrative in all respects.

What is claimed is:

1. A semiconductor device comprising:
a field insulating film which includes a first surface and a second surface opposite to each other in a first direction;
a first protruding insulation pattern disposed on the first surface of the field insulating film;
a second protruding insulation pattern disposed on the first surface of the field insulating film and spaced apart from the first protruding insulation pattern in a second direction, a thickness of the second protruding insulation pattern in the first direction being different from a thickness of the first protruding insulation pattern in the first direction;
a channel region disposed between the first protruding insulation pattern and the second protruding insulation pattern; and
a gate electrode disposed on the channel region, the first protruding insulation pattern, and the second protruding insulation pattern,
wherein the gate electrode includes a first connecting gate electrode, a second connecting gate electrode, and a body gate electrode disposed between the first connecting gate electrode and the second connecting gate electrode,
wherein the first connecting gate electrode overlaps the first protruding insulation pattern in the first direction,
wherein the second connecting gate electrode overlaps the second protruding insulation pattern in the first direction, and
wherein the body gate electrode is disposed between the first protruding insulation pattern and the second protruding insulation pattern.

2. The semiconductor device of claim 1,
wherein a thickness of the body gate electrode in the first direction is greater than a thickness of the first connecting gate electrode in the first direction.

3. The semiconductor device of claim 1,
wherein the thickness of the first connecting gate electrode in the first direction is equal to a thickness of the second connecting gate electrode in the first direction.

4. The semiconductor device of claim 1, further comprising:
a gate insulating film disposed between the gate electrode and the channel region, between the gate electrode and the first protruding insulation pattern, and between the gate electrode and the second protruding insulation pattern,
wherein the body gate electrode includes a first surface and a second surface that are opposite to each other in the first direction, and the second surface of the body gate electrode faces the field insulating film, and
wherein the gate insulating film extends along the second surface of the body gate electrode, and does not extend along the first surface of the body gate electrode.

5. The semiconductor device of claim 4,
wherein the first connecting gate electrode includes a first surface and a second surface that are opposite to each other in the first direction, and
wherein the gate insulating film extends along the first surface of the first connecting gate electrode and the second surface of the first connecting gate electrode.

6. The semiconductor device of claim 1,
wherein the channel region includes a first side wall and a second side wall that are opposite to each other in the second direction, and
wherein a thickness of the body gate electrode in the second direction on the first side wall of the channel region is equal to a thickness of the body gate electrode in the second direction on the second side wall of the channel region.

7. The semiconductor device of claim 1,
wherein the channel region includes a channel pattern spaced apart from the first surface of the field insulating film, and the gate electrode encloses the channel pattern in a cross-sectional view.

8. The semiconductor device of claim 7,
wherein the channel region includes a plurality of channel patterns spaced apart from each other in the first direction.

9. The semiconductor device of claim 1, further comprising:
a fin-shaped pattern disposed between the first protruding insulation pattern and the second protruding insulation pattern,
wherein the fin-shaped pattern includes the channel region, and a lower region disposed below the channel region and directly connected to the channel region,
wherein the lower region is in contact with the field insulating film, and
wherein the channel region is not in contact with the field insulating film.

10. The semiconductor device of claim 1, further comprising:
a third protruding insulation pattern spaced apart from the first protruding insulation pattern in the second direction,
wherein the first protruding insulation pattern is disposed between the second protruding insulation pattern and the third protruding insulation pattern,
wherein a thickness of the third protruding insulation pattern in the first direction is different from the thickness of the first protruding insulation pattern in the first direction, and
wherein the thickness of the third protruding insulation pattern in the first direction is different from the thickness of the second protruding insulation pattern in the first direction.

11. The semiconductor device of claim 1, further comprising:
a source/drain pattern connected to the channel region,
wherein the first protruding insulation pattern includes a first portion that overlaps the gate electrode in the second direction, and a second portion that overlaps the source/drain pattern in the second direction, and
wherein a thickness of the first protruding insulation pattern in the first direction at the first portion of the first protruding insulation pattern is greater than a thickness of the first protruding insulation pattern in the first direction at the second portion of the first protruding insulation pattern.

12. A semiconductor device comprising:
a field insulating film which includes an upper surface and a lower surface opposite to each other in a vertical direction;
a channel region disposed above the upper surface of the field insulating film, the channel region including a first side wall and a second side wall opposite to each other in a horizontal direction;
a first protruding insulation pattern disposed on the first side wall of the channel region, and in contact with the upper surface of the field insulating film; and
a gate structure disposed on the channel region and the first protruding insulation pattern, the gate structure including a gate electrode and a gate insulating film,
wherein the gate electrode includes a body gate electrode disposed on the first side wall of the channel region and the second side wall of the channel region, and a first connecting gate electrode and a second connecting gate electrode extending from the body gate electrode in the horizontal direction,
wherein a thickness of the body gate electrode in the horizontal direction on the first side wall of the channel region is equal to a thickness of the body gate electrode in the horizontal direction on the second side wall of the channel region,
wherein a height of the body gate electrode in the vertical direction is greater than a height of the first connecting gate electrode in the vertical direction and a height of the second connecting gate electrode in the vertical direction,
wherein the first connecting gate electrode is disposed on the first side wall of the channel region, and overlaps the first protruding insulation pattern in the vertical direction,
wherein the second connecting gate electrode is disposed on the second side wall of the channel region,
wherein each of the first connecting gate electrode and the second connecting gate electrode includes an upper surface and a lower surface opposite to each other in the vertical direction,
wherein the lower surface of the first connecting gate electrode and the lower surface of the second connecting gate electrode face the field insulating film, and
wherein a height from the lower surface of the field insulating film to the upper surface of the first connecting gate electrode is greater than a height from the lower surface of the field insulating film to the upper surface of the second connecting gate electrode.

13. The semiconductor device of claim 12,
wherein a thickness of the first connecting gate electrode in the vertical direction is equal to a thickness of the second connecting gate electrode in the vertical direction.

14. The semiconductor device of claim 12,
wherein the body gate electrode includes an upper surface and a lower surface opposite to each other in the vertical direction,
wherein the lower surface of the body gate electrode faces the field insulating film, and
wherein the gate insulating film contacts the lower surface of the body gate electrode, and does not contact the upper surface of the body gate electrode.

15. The semiconductor device of claim 12, further comprising:
a second protruding insulation pattern disposed on the upper surface of the field insulating film, and spaced apart from the first protruding insulation pattern in the horizontal direction,
wherein the second connecting gate electrode overlaps the second protruding insulation pattern in the vertical direction.

16. The semiconductor device of claim 12,
wherein the channel region includes a channel pattern spaced apart from the upper surface of the field insulating film, and
wherein the gate electrode encloses the channel pattern in a cross-sectional view.

17. The semiconductor device of claim 16,
wherein the channel region includes a plurality of channel patterns spaced apart in the vertical direction.

18. The semiconductor device of claim 12, further comprising:
a fin-shaped pattern disposed between the first protruding insulation pattern and a second protruding insulation pattern,
wherein the fin-shaped pattern includes the channel region, and a lower region disposed below the channel region and directly connected to the channel region,
wherein the lower region is in contact with the field insulating film, and
wherein the channel region is not in contact with the field insulating film.

19. A semiconductor device comprising:
a field insulating film which includes a first surface and a second surface opposite to each other in a first direction;
a first protruding insulation pattern disposed on the first surface of the field insulating film;
a second protruding insulation pattern disposed on the first surface of the field insulating film, and spaced apart from the first protruding insulation pattern in a second direction, a height of the second protruding insulation pattern in the first direction being different from a height of the first protruding insulation pattern in the first direction;
a channel region spaced apart from the first surface of the field insulating film in the first direction;
a gate electrode disposed on the first protruding insulation pattern and the second protruding insulation pattern, and enclosing the channel region;
source/drain patterns connected to the channel region, and disposed on both sides of the gate electrode; and
a gate contact disposed on the gate electrode, and electrically connected to the gate electrode,
wherein the gate electrode includes a first connecting gate electrode, a second connecting gate electrode, and a body gate electrode disposed between the first connecting gate electrode and the second connecting gate electrode,
wherein the first connecting gate electrode overlaps the first protruding insulation pattern in the first direction,
wherein the second connecting gate electrode overlaps the second protruding insulation pattern in the first direction,
wherein the body gate electrode is disposed between the first protruding insulation pattern and the second protruding insulation pattern, and
wherein a height of the body gate electrode in the first direction is greater than a height of the first connecting gate electrode in the first direction.

20. The semiconductor device of claim 19,
wherein the channel region includes a plurality of channel patterns spaced apart from each other in the first direction.
